(19) United States
(12) Patent Application Publication
(10) Pub. No.: US 2021/0055210 A1
(43) Pub. Date: Feb. 25, 2021

(54) DEVICES, SYSTEMS AND METHODS UTILIZING AN IMPROVED OPTICAL ABSORPTION MODEL FOR DIRECT-GAP SEMICONDUCTORS

(71) Applicants: Shane Johnson, Chandler, AZ (US); Stephen Schaefer, Tempe, AZ (US); Shang Gao, Jinan (CN)

(72) Inventors: Shane Johnson, Chandler, AZ (US); Stephen Schaefer, Tempe, AZ (US); Shang Gao, Jinan (CN)

(73) Assignee: Arizona Board of Regents on behalf of Arizona State University, Scottsdale, AZ (US)

(21) Appl. No.: 16/999,975

(22) Filed: Aug. 21, 2020

Related U.S. Application Data
(60) Provisional application No. 62/890,324, filed on Aug. 22, 2019.

(51) Int. Cl. G01N 21/31; G01K 11/00; G06F 17/18; G06F 17/17

(52) U.S. Cl. CPC G01N 21/31; G01K 11/00; H01L 29/20; G06F 17/17; G06F 17/18

(57) ABSTRACT

A method for determining a characteristic of a direct-gap semiconductor comprises measuring at least one optical constant of a first sample of a direct-gap semiconductor with an optical spectrometer, calculating an estimated value of an optical parameter of the first sample of the direct-gap semiconductor based on fitting the model α_{g}(ln(1+e^{(hν-E}^{_{g}}^{)/(pE}^{ᵤ}⁾)/ln(2))^{p} to an optical absorption curve based on the at least one optical constant, obtaining at least one second value of the optical parameter, and calculating an estimated characteristic of the direct-gap semiconductor from the estimated value of the optical parameter and the obtained second value of the optical parameter. A method for determining a temperature of a direct-gap semiconductor and a system for determining a characteristic of a direct-gap semiconductor are also disclosed.

### CROSS-REFERENCE TO RELATED APPLICATIONS

This application claims priority to U.S. Provisional Patent Application No. 62/890,324, filed on Aug. 22, 2019, incorporated herein by reference in its entirety.

### STATEMENT REGARDING FEDERALLY SPONSORED RESEARCH OR DEVELOPMENT

This invention was made with government support under 1410393 awarded by the National Science Foundation. The government has certain rights in the invention.

### BACKGROUND OF THE INVENTION

The optical absorption edge is a key property determining the optical emission spectrum in direct-bandgap III-V semiconductors. It reflects the influence of numerous properties including the joint optical density of states, the optical transition strength, and the presence of localized tail states at the band edges. Precise and repeatable measurement of the absorption edge is crucial for assessing material quality and provides insight to the density of states and transition probabilities in the material. Specifically, these include the fundamental bandgap energy, the magnitude of the absorption coefficient at the bandgap energy, and the characteristic width of the Urbach tail that embodies the manifestation of localized states near the band edges due to lattice disorder. Examining the absorption coefficient in terms of these model parameters provides insight into the optical joint density of states, the optical transition strength, and Coulomb enhancement of the optical transition strength. Existing models typically treat interband and tail state absorption separately, which can hinder the extraction of the bandgap energy from the absorption coefficient spectrum.

The fundamental bandgap energy of a semiconductor is defined as the energy separation between the continuum valence band maximum and continuum conduction band minimum. This definition is precise in the absence of defect or tail states that cause sub-bandgap absorption. The unavoidable presence of these localized states results in a degree of ambiguity about the determination of the bandgap energy. The bandgap energy of bulk semiconductors is at times identified as the energy at which the first derivative of the absorption coefficient α, extinction coefficient k, or imaginary part of the dielectric function £₂ attains its maximum value. This so-called first derivative maximum method approximates the energy at which the joint optical density of states increases at the greatest rate. For direct-bandgap bulk semiconductors this corresponds to the onset of optical transitions involving the edges of valence and conduction band continuum states once the photon energy equals or exceeds the fundamental bandgap energy. The first derivative maximum method is also used to identify the ground state transition energy for quantum-confined structures such as quantum wells or superlattices. Nevertheless, the first derivative maximum provides little insight into the shape of the absorption edge that can be strongly influenced by the Coulomb interaction between the electrons and holes and the presence of localized states near the continuum band edges. These effects influence the fundamental bandgap energy as defined by the energy separation of the continuum band edges.

What is needed in the art is an improved model that treats interband and tail state absorption simultaneously, enabling highly accurate and repeatable measurement of the bandgap energy of direct-gap semiconductors such as GaAs, GaSb, InAs, or InSb. The improved model should also measure the Urbach energy describing the density of sub-bandgap tail states. The model should also be capable of describing absorption for any direct-gap semiconductor while making no assumptions about the energy dependence of the dipole and momentum matrix elements, one of which is commonly taken to be constant with respect to photon energy in conventional models.

### SUMMARY OF THE INVENTION

In one aspect, a method for determining a characteristic of a direct-gap semiconductor comprises measuring at least one optical constant of a first sample of a direct-gap semiconductor with an optical spectrometer, calculating an estimated value of an optical parameter of the first sample of the direct-gap semiconductor based on fitting the model α_{g}(ln(1+e^{(hν-E}^{_{g}}^{)/pE}^{ᵤ}⁾/ln(2))^{p} to an optical absorption curve based on the at least one optical constant, obtaining at least one second value of the optical parameter, and calculating an estimated characteristic of the direct-gap semiconductor from the estimated value of the optical parameter and the obtained second value of the optical parameter.

In one embodiment, the method further comprises obtaining at least one predetermined absorption characteristic of at least one known material as the second value of the optical parameter, wherein the characteristic of the direct-gap semiconductor is a composition of the direct-gap semiconductor, and wherein the optical parameter is an absorption characteristic. In one embodiment, the model is fit using a least-squares fitting algorithm to measured optical absorption curves over a range spanning three times Eᵤ of the direct-gap semiconductor below the bandgap energy to 0.2 eV above the bandgap energy.

In one embodiment, the method further comprises the steps of measuring at least one optical constant of a second sample of a direct-gap semiconductor with the optical spectrometer, and determining a second amplitude of an absorption knee of the second sample as the second value of the optical parameter, based on fitting the model α_{g}(ln(1+e^{(hν-E}^{_{g}}^{)/pE}^{ᵤ}⁾/ln(2))^{p} to an optical absorption curve based on the at least one optical constant of the second sample, wherein the characteristic of the direct-gap semiconductor is an optical quality of the direct-gap semiconductor, and wherein the optical parameter is a first amplitude of an absorption knee of the first sample.

In one embodiment, the model is fit using a least-squares fitting algorithm to measured optical absorption curves over a range spanning three times Eᵤ of the direct-gap semiconductor below the bandgap energy to 0.2 eV above the bandgap energy. In one embodiment, the method further comprises the steps of measuring at least one optical constant of a second sample of a direct-gap semiconductor with the optical spectrometer, and determining a second Urbach energy parameter of the second sample as the second value of the optical parameter, based on fitting the model α_{g}(ln(1+e^{(hν-E}^{_{g}}^{)/pE}^{ᵤ}⁾/ln(2))^{p} to an optical absorption curve based on the at least one optical constant of the second sample, wherein the characteristic of the direct-gap semiconductor is an optical quality of the direct-gap semiconductor, and wherein the optical parameter is a first Urbach energy of the first sample.

In one embodiment, the model is fit using a least-squares fitting algorithm to measured optical absorption curves over a range spanning three times Eᵤ of the direct-gap semiconductor below the bandgap energy to 0.2 eV above the bandgap energy. In one embodiment, the direct-gap semiconductor comprises a material selected from the group consisting of Ga, As, In, and Sb.

In one aspect, a method for determining a temperature of a direct-gap semiconductor comprises measuring at least one optical constant of a sample of a direct-gap semiconductor with an optical spectrometer, determining a bandgap energy of the sample based on fitting the model α_{g}(ln(1+e^{(hν-E}^{_{g}}^{)/pE}^{ᵤ}⁾/ln(2))^{p} to an optical absorption curve based on the at least one optical constant, comparing the bandgap energy of the sample to a known absorption characteristic of a reference material, and calculating a temperature of the first sample based on a temperature dependence of the bandgap energy of the first sample and the bandgap energy of the reference material.

In one embodiment, the model is fit using a least-squares fitting algorithm to measured optical absorption curves over a range spanning three times Eᵤ of the direct-gap semiconductor below the bandgap energy to 0.2 eV above the bandgap energy. In one embodiment, the absorption characteristic is the bandgap energy. In one embodiment, the direct-gap semiconductor comprises a material selected from the group consisting of Ga, As, In, and Sb.

In one aspect, a system for determining a characteristic of a direct-gap semiconductor comprises a spectroscopic device configured to measure at least one optical constant of a sample of a direct-gap semiconductor, a computing device communicatively connected to the spectroscopic device, comprising a processor and a non-transitory computer-readable medium with instructions stored thereon, which when executed by a processor, perform steps comprising calculating an estimated value of an optical parameter of the first sample of the direct-gap semiconductor based on fitting the model α_{g}(ln(1+e^{(hν-E}^{_{g}}^{)/pE}^{ᵤ}⁾/ln(2))^{p} to an optical absorption curve based on the at least one optical constant, obtaining at least one second value of the optical parameter, and calculating an estimated characteristic of the direct-gap semiconductor from the estimated value of the optical parameter and the obtained second value of the optical parameter.

In one embodiment, the system further comprises an optical coupling medium positioned between the spectroscopic device and the sample of the direct-gap semiconductor. In one embodiment, the steps further comprise obtaining at least one predetermined absorption characteristic of at least one known material as the second value of the optical parameter, wherein the characteristic of the direct-gap semiconductor is a composition of the direct-gap semiconductor, and wherein the optical parameter is an absorption characteristic.

In one embodiment, the model is fit using a least-squares fitting algorithm to measured optical absorption curves over a range spanning three times Eᵤ of the direct-gap semiconductor below the bandgap energy to 0.2 eV above the bandgap energy. In one embodiment, the absorption characteristic is the bandgap energy.

In one embodiment, the steps further comprise measuring at least one optical constant of a second sample of a direct-gap semiconductor with the optical spectrometer, and determining a second amplitude of an absorption knee of the second sample as the second value of the optical parameter, based on fitting the model α_{g}(ln(1+e^{(hν-E}^{_{g}}^{)/pE}^{ᵤ}⁾/ln(2))^{p} to an optical absorption curve based on the at least one optical constant of the second sample, wherein the characteristic of the direct-gap semiconductor is an optical quality of the direct-gap semiconductor, and wherein the optical parameter is a first amplitude of an absorption knee of the first sample. In one embodiment, the model is fit using a least-squares fitting algorithm to measured optical absorption curves over a range spanning three times Eᵤ of the direct-gap semiconductor below the bandgap energy to 0.2 eV above the bandgap energy.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is a graph showing a normalized coefficient model;

FIG. 2 is a flow chart of a method for determining a composition of a direct-gap semiconductor according to one embodiment;

FIG. 3 is a diagram of an exemplary system for determining the composition of a direct-gap semiconductor;

FIG. 4 is a flow chart of a method for determining a temperature of a direct-gap semiconductor according to one embodiment;

FIG. 5 is a diagram of an exemplary system for determining the temperature of a direct-gap semiconductor;

FIG. 6 is a flow chart of a method for characterizing optical quality of direct-gap semiconductors according to one embodiment;

FIG. 7A is a diagram of an exemplary system for quantifying the optical quality of one or more direct-gap semiconductors;

FIG. 7B is a diagram of an exemplary system for quantifying the optical quality of one or more direct-gap semiconductors;

FIG. 7C is a graph of absorption coefficient α as a function of photon energy relative to the bandgap hν−E₉ for semi-insulating GaAs sample A and undoped GaSb, InAs, and InSb substrates;

FIG. 8A is a graph of complex index of refraction for three different semi-insulating GaAs samples measured by spectroscopic ellipsometry;

FIG. 8B is a graph of complex dielectric function for three different semi-insulating GaAs samples measured by spectroscopic ellipsometry;

FIG. 9 is a graph of the calculated absorption amplitude and the experimental absorption amplitudes and absorption knee for GaAs, GaSb, InAs, and InSb;

FIG. 10 is a graph of GaAs bandgap energies at 297 K determined from the absorption edge model disclosed herein and the measured data for various optical constants and analytical methods;

FIG. 11 is a graph of the position of the first derivative maximum to the model parameter as a function of power law for GaAs, GaSb, InAs, InSb, and for Eᵤ=1 meV;

FIG. 12 is a graph of the ratio of the model parameters Eₘ/E_{g} and Eₘ/Eₑₓ as a function of model parameter p_{g} for GaAs, GaSb, InAs, and InSb; and

FIG. 13A, FIG. 13B, and FIG. 13C are graphs showing experimental results.

### DETAILED DESCRIPTION OF THE INVENTION

It is to be understood that the figures and descriptions of the present invention have been simplified to illustrate elements that are relevant for a more clear comprehension of the present invention, while eliminating, for the purpose of clarity, many other elements found in devices, systems and methods for characterizing direct-gap semiconductors. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

In some aspects of the present invention, software executing the instructions provided herein may be stored on a non-transitory computer-readable medium, wherein the software performs some or all of the steps of the present invention when executed on a processor.

Aspects of the invention relate to algorithms executed in computer software. Though certain embodiments may be described as written in particular programming languages, or executed on particular operating systems or computing platforms, it is understood that the system and method of the present invention is not limited to any particular computing language, platform, or combination thereof. Software executing the algorithms described herein may be written in any programming language known in the art, compiled or interpreted, including but not limited to C, C++, C#, Objective-C, Java, JavaScript, Python, PHP, Perl, Ruby, or Visual Basic. It is further understood that elements of the present invention may be executed on any acceptable computing platform, including but not limited to a server, a cloud instance, a workstation, a thin client, a mobile device, an embedded microcontroller, a television, or any other suitable computing device known in the art.

Parts of this invention are described as software running on a computing device. Though software described herein may be disclosed as operating on one particular computing device (e.g. a dedicated server or a workstation), it is understood in the art that software is intrinsically portable and that most software running on a dedicated server may also be run, for the purposes of the present invention, on any of a wide range of devices including desktop or mobile devices, laptops, tablets, smartphones, watches, wearable electronics or other wireless digital/cellular phones, televisions, cloud instances, embedded microcontrollers, thin client devices, or any other suitable computing device known in the art.

Similarly, parts of this invention are described as communicating over a variety of wireless or wired computer networks. For the purposes of this invention, the words “network”, “networked”, and “networking” are understood to encompass wired Ethernet, fiber optic connections, wireless connections including any of the various 802.11 standards, cellular WAN infrastructures such as 3G or 4G/LTE networks, Bluetooth®, Bluetooth® Low Energy (BLE) or Zigbee® communication links, or any other method by which one electronic device is capable of communicating with another. In some embodiments, elements of the networked portion of the invention may be implemented over a Virtual Private Network (VPN).

Referring now in detail to the drawings, in which like reference numerals indicate like parts or elements throughout the several views, in various embodiments, presented herein are devices, systems and methods utilizing an improved optical absorption model for direct-gap semiconductors.

In its textbook form, the optical absorption spectrum of a semiconductor is expressed as a product of the joint optical density of states ρ(hν) (cm⁻³·eV⁻¹) and a transition strength S(hν) (cm²·eV) with

α(hν)=ρ(hν)·S(hν) Equation 1

The joint optical density of states depends on the electron and hole density of states, which are determined by the band structure in the vicinity of the fundamental bandgap. For direct-gap semiconductors, such as III-V binaries, electrons and holes have approximately parabolic band dispersion near the band edges. The corresponding joint optical density of states exhibits a square root dependence on photon energy hν, with

$$ρ ( h v ) = \frac{8 \sqrt{2} π}{{h}^{3}} {( {m}_{e} \frac{{m}_{c} {m}_{v}}{{m}_{c} + {m}_{v}} )}^{3 / 2} \sqrt{h v - {E}_{g}} \qquad Equation 2$$

where mₑ is the free electron mass, and m_{c} and m_{ν} are the dimensionless effective masses of the conduction band electrons and valence band holes, respectively. In the absence of strain the light hole and heavy hole bands are degenerate at the Γ point, and the joint optical density of states is dominated by the smaller electron effective mass. Here ρ(hν) is the density of states in the absence of band filling effects, such as the Moss-Burstein shift and bandgap renormalization. These effects are negligible for measurements where the photoexcited carrier concentration is well below degeneracy.

The transition strength in Equation 1 can be expressed in terms of a dimensionless transition strength S₀(hν) with

$$S ( h v ) = \frac{h {e}^{2}}{4 c {ɛ}_{0} {m}_{e} n ( h v )} {S}_{0} ( h v ) \qquad Equation 3$$

where h is Planck's constant, c is the speed of light, E₀ is the vacuum permittivity, e is the electron charge, and n(hν) is the refractive index that typically has a weak dependence on photon energy. The absorption coefficient changes by orders of magnitude in the vicinity of the band edge of the materials disclosed herein, while the refractive index changes by less than 2% and as such is assumed to be an average constant value.

The transition strength S₀ describes the probability of a given optical transition and is described by the optical perturbation to the crystal Hamiltonian due to the presence of light. According to Fermi's golden rule the rate of optical transitions is proportional to the perturbed Hamiltonian matrix element for interband transitions. In the long-wavelength dipole approximation where the wavelength of the perturbing optical field is much greater than the unit cell, the transition strength associated with this matrix element is equivalently related to either the momentum matrix element [symbol] ψₕ|p|ψₑ [symbol] or dipole matrix element [symbol] ψₕ|r|ψₑ [symbol] as

$${S}_{0} = ( \frac{2}{{m}_{e}} ) \frac{{\vert 〈 {ψ}_{h} \vert p \vert {ψ}_{e} 〉 \vert}^{2}}{h v} = ( \frac{8 {π}^{2} {m}_{e}}{{h}^{2}} ) {\vert 〈 {ψ}_{h} \vert r \vert {ψ}_{e} 〉 \vert}^{2} h v = \frac{4 π}{h} \sqrt{{\vert 〈 {ψ}_{h} \vert p \vert {ψ}_{e} 〉 \vert}^{2} \cdot {\vert 〈 {ψ}_{h} \vert r \vert {ψ}_{e} 〉 \vert}^{2}} \qquad Equation 4$$

In practice, either the momentum matrix element, dipole matrix element, or transition strength is assumed to be a constant that is independent of photon energy in much of the analyses performed in the literature. The assumption that any one of these three is constant assumes an energy dependence for the other two. Using Equation 1 through Equation 4, the absorption coefficient is expressed in terms of the momentum matrix element [symbol] ψₕ|p|ψₑ [symbol] in Equation 5A, the dipole matrix element [symbol] ψₕ|r|ψₑ [symbol] in Equation 5B, and the product of the two in Equation 5C.

$$\begin{matrix}α ( hv ) = \frac{4 \sqrt{2} π {e}^{2}}{nc {ɛ}_{0} {h}^{2} \sqrt{{m}_{e}}} {( \frac{{m}_{c} {m}_{v}}{{m}_{c} + {m}_{v}} )}^{3 / 2} {\vert 〈 {ψ}_{h} \vert p \vert {ψ}_{e} 〉 \vert}^{2} \cdot {( hv - {E}_{g} )}^{1 / 2} {( hv )}^{- 1} & Equation 5 A \\ α ( hv ) = \frac{16 \sqrt{2} {π }^{3} {e}^{2} {m}_{e}^{3 / 2}}{nc {ɛ}_{0} {h}^{2}} {( \frac{{m}_{c} {m}_{v}}{{m}_{c} + {m}_{v}} )}^{3 / 2} {\vert 〈 {ψ}_{h} \vert r \vert {ψ}_{e} 〉 \vert}^{2} \cdot {( hv - {E}_{g} )}^{1 / 2} hv & Equation 5 B \\ α ( hv ) = \frac{8 \sqrt{2} {π }^{3} {e}^{2} \sqrt{{m}_{e}}}{nc {ɛ}_{0} {h}^{2}} {( \frac{{m}_{c} {m}_{v}}{{m}_{c} + {m}_{v}} )}^{3 / 2} \sqrt{\begin{matrix}{\vert 〈 {ψ}_{h} \vert p \vert {ψ}_{e} 〉 \vert}^{2} \cdot \\ {\vert 〈 {ψ}_{h} \vert r \vert {ψ}_{e} 〉 \vert}^{2}\end{matrix}} \cdot {( hv - {E}_{g} )}^{1 / 2} & Equation 5 C\end{matrix}$$

By writing the equations in this form, the photon energy dependence of each of the three assumptions is explicitly shown. In addition to the square root density states term, the constant momentum matrix element approximation results in a one over energy term, the constant dipole matrix element results in a linear energy term, and the constant transition strength approximation has no additional energy dependent term. The choice of which is taken to be constant influences the interpretation of the behavior of the absorption coefficient above the bandgap energy.

This treatment of the absorption edge considers only the continuum states involved in transitions at and above the fundamental bandgap energy and does not account for free exciton absorption, the Coulomb enhancement of absorption near the bandgap, or the broadening effects of thermal and frozen in crystal lattice disorder. Even high-quality materials exhibit an Urbach absorption edge that is mainly due to the electron-phonon interaction. Excitonic absorption is a significant effect in high purity material, particularly at low temperatures, and results in absorption peaks below the bandgap energy.

Furthermore, the Coulomb interaction between free electrons and holes results in an enhancement of absorption near the bandgap that is dependent on the free exciton binding energy that typically scales with bandgap energy in the III-Vs. The Coulomb interaction is a multi-particle phenomenon involving both an electron and hole and as such cannot be treated within the free electron band structure framework, but rather requires the addition of the electron-hole Coulomb potential to the crystal Hamiltonian. Thus the Coulomb interaction can modify both the density of states and the transition strength. The effect of the Coulomb interaction is large near the bandgap energy and asymptotically approaches unity at energies above the bandgap energy, which has been quantified by an enhancement factor described as

$$F ( h v ) = \frac{2 π \sqrt{\frac{{E}_{e x}}{h v - {E}_{g}}}}{1 - {e}^{- 2 π \sqrt{\frac{{E}_{e x}}{h v - {E}_{g}}}}} \qquad Equation 6$$

The exciton binding energy Eₑₓ scales with bandgap energy and is experimentally determined as 4.0 meV for GaAs, 2.1 meV for GaSb, 1.0 meV for InAs, and 0.4 meV for InSb. As such, the Coulomb enhancement of absorption is expected to increase with bandgap energy.

A model is disclosed that in one embodiment evaluates the onset of absorption at the fundamental bandgap and that encompasses the asymptotic behaviors of the absorption coefficient above and below the bandgap. The model is shown in Equation 7A and Equation 7B and contains 5 parameters: the bandgap energy E_{g}, determined by the behavior of the absorption coefficient above bandgap; the characteristic Urbach energy Eᵤ, based on the slope of the absorption tail below the bandgap; the magnitude of the absorption coefficient at the bandgap energy α_{y}; and the power law dependence p(hν) of the absorption coefficient above the bandgap that is comprised of a constant term p_{g} that describes the power law at the bandgap and a photon energy hν dependent term that describes the variation in the power law above the bandgap with characteristic energy, Eₘ.

$$\begin{matrix}α ( h v ) = {{α}_{g} [ \frac{ln ( 1 + {e}^{( h v - {E}_{g} ) / p {E}_{u}} )}{ln 2} ]}^{p} & Equation 7 A \\ p ( h v ) = {p}_{g} + \frac{h v - {E}_{g}}{{E}_{m}} & Equation 7 B\end{matrix}$$

For energies above the bandgap, hν>E_{g}, the asymptotic behavior reflects optical absorption involving continuum states and is specified as a power law with

$$α ( h v ) = {{α}_{g} ( \frac{h v - {E}_{g}}{ln ( 2 ) \cdot p ( hv ) \cdot {E}_{u}} )}^{p ( h v )} \qquad Equation 8$$

For energies below the bandgap, hν≤E_{g}, the asymptotic behavior reflects optical absorption involving localized tail states specified by an exponential Urbach tail with

α(hν)=α_{g}(ln 2)^{-p(hν)}e^{(hν-E}^{_{g}}^{)/E}^{ᵤ}≅α_{g}(ln 2)^{-p}^{_{g}}e^{(hν-E}^{_{g}}^{)/E}^{ᵤ} Equation 9

where the right-hand approximation is valid for abrupt absorption edges, with Eᵤ<<Eₘ.

Examining the absorption coefficient in terms of these model parameters provides insight into the optical joint density of states, the optical transition strength, and Coulomb enhancement of the optical transition strength. As an example, the parabolic single-electron band model predicts a square root density of states with power law one half and an Urbach tail width that approaches zero. The model in Equation 7 does not describe bound exciton absorption peaks when present in the data, which would be modeled by an additional function.

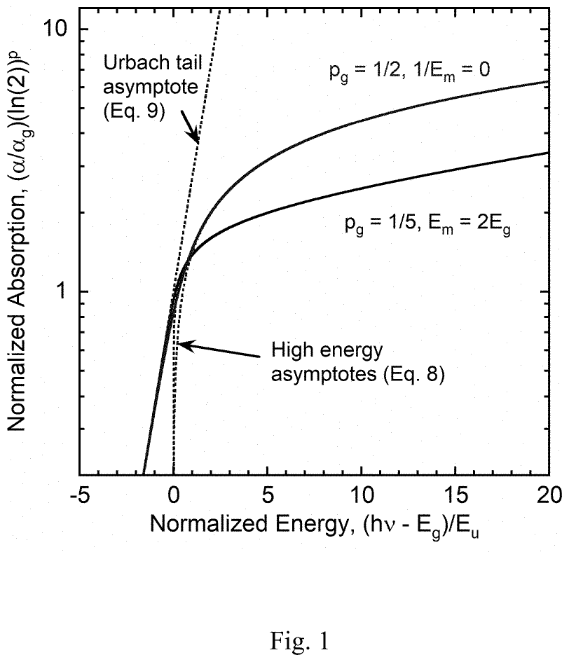

The model is shown in FIG. 1, where it is plotted in terms of normalized absorption coefficient (α/α_{g})(ln 2)^{p} as a function of normalized energy (hν−E_{g})/Eᵤ. Two cases are illustrated: i) for a square root density of states and a constant transition strength, where the power law is a constant one half with p_{g}=½ and 1/Eₘ=0, and ii) for a strong Coulomb interaction, where the power law is small with p_{g}=⅕ and Eₘ=2E_{g}. The normalization (α/α_{g})(ln 2)^{p} is selected such that the Urbach tail asymptotes of the two curves coincide. The power law p_{g}, which is related to the optical density of states and the influence of the Coulomb interaction, dictates the sharpness of the absorption turn-on at the bandgap energy. The characteristic energy Eₘ is related to the energy dependence of the optical transition strength (matrix element) and the decay in the strength of Coulomb interaction for optical transitions at photon energies above the bandgap. The dashed lines in FIG. 1 show the low and high energy asymptotic expressions, Equation 8 and Equation 9, respectively.

Although knowledge of the absorption coefficient at the bandgap energy is useful, it does not fully describe the overall magnitude of the absorption near the bandgap that is strongly influenced by the Coulomb interaction in addition to the density of states. For instance, the effective cutoff wavelength of a photodetector is typically shorter than the bandgap wavelength, as thin film materials can be transparent right at the bandgap. Therefore a better figure of merit for comparing the optical absorption strength of different materials for device applications is the “knee” of the absorption spectrum when viewed on a log scale, which identifies the magnitude of the absorption coefficient as it rolls over above the bandgap. The position of the absorption spectrum knee Eₖ is specified by the energy where the radius of curvature rₐ of the absorption spectrum has a minimum value

$${r}_{k} = {min}_{h v} {r}_{a} ,$$

with

$${r}_{a} = \vert \frac{{( {x}^{′2} + {y}^{′ 2} )}^{3 / 2}}{{x}^{′} {y}^{″} - {y}^{′} {x}^{″}} \vert = \vert \frac{{a ( {( \frac{1}{a} )}^{2} + {( \frac{1}{α ( h v )} \frac{d α}{d h v} )}^{2} )}^{3 / 2}}{\frac{1}{α ( h v )} \frac{{d}^{2} α}{d h {v}^{2}} - {( \frac{1}{α ( h v )} \frac{d α}{d h v} )}^{2}} \vert \qquad Equation 10$$

Here x=hν/α and y=ln(α(hν)/b) are the dimensionless energy and absorption coefficient normalized by the constants a with units of energy and b with units of inverse length. The parameter b does not appear in Equation 10 as the derivatives of y are independent of the vertical scale when the absorption coefficient is observed on a log scale. The parameter a scales the horizontal energy axis to the energy range of interest, as the range selected affects the observed energy position of the knee. The first and second derivatives are x′=1/a, y′=α′/α, x″=0, and y″=α″/α−(α′/α)². The radius of curvature of ln(α(hν)) exhibits a single well-defined minimum that is observed above the bandgap energy E₉, thus defining the position Eₖ and amplitude αₖ of the knee in the absorption spectrum.

The absorption edge also manifests itself in the imaginary parts of the complex index of refraction, ñ=n+ik, and the complex dielectric function, \tilde{ε}=ε₁+iε₂, as is apparent in the following relationships between the optical constants.

$$\begin{matrix}α = \frac{4 π khv}{hc} & Equation 11 A \\ {ɛ}_{1} = {n}^{2} - {k}^{2} & Equation 11 B \\ {ɛ}_{2} = 2 nk & Equation 11 C \\ {n}^{2} = \frac{1}{2} [ \sqrt{{ɛ}_{1}^{2} + {ɛ}_{2}^{2}} + {ɛ}_{1} ] & Equation 11 D \\ {k}^{2} = \frac{1}{2} [ \sqrt{{ɛ}_{1}^{2} + {ɛ}_{2}^{2}} - {ɛ}_{1} ] & Equation 11 E\end{matrix}$$

As such the absorption edge model in Equation 7 is also suitable for examination of the extinction coefficient k and the imaginary dielectric coefficient ε₂.

The first derivative method of identifying bandgap energy finds the energy where the absorption edge increases at the greatest rate. Numerical calculation of the derivative at each data point is performed by the center-difference formula

$$\frac{df [ j ]}{dhv [ j ]} = \frac{f [ j + 1 ] - f [ j - 1 ]}{hv [ j + 1 ] - hv [ j - 1 ]} \qquad Equation 12$$

where f is the measured discrete data as a function of energy, which is either the absorption coefficient α, the extinction coefficient k, or the imaginary dielectric coefficient ε₂. If the energy spacing of the data is constant, the denominator hν[j+1]−hν[j−1] may be replaced by 2Δhν, where Δhν is the constant energy spacing. The center-difference point-by-point derivative calculation does not shift of the maximum of the first derivative, unlike backward or forward difference formulas that shift the derivative by ±Δhν, respectively.

Embodiments of the invention rely on a model that treats interband and tail state absorption simultaneously, enabling highly accurate and repeatable measurement of the bandgap energy of direct-gap semiconductors such as GaAs, GaSb, InAs, or InSb. The Urbach energy describing the density of sub-bandgap tail states is also measured. The model may be used to describe absorption for any direct-gap semiconductor and makes no assumptions about the energy dependence of the dipole and momentum matrix elements, one of which is commonly taken to be constant with respect to photon energy in conventional models.

Embodiments of the invention utilize a five parameter model formulated to describe the key characteristics of the optical absorption edge of direct bandgap semiconductors. These parameters include the bandgap energy, based on the behavior of the absorption coefficient above bandgap; the characteristic Urbach energy, based on the width of the absorption tail below the bandgap; the magnitude of the absorption coefficient at the bandgap energy, and the power law dependence of the absorption coefficient above the bandgap. The power law is comprised of a constant term that describes the power law at the bandgap and a photon energy dependent term that describes variations in the power law above the bandgap using a characteristic energy. The model provides highly accurate and repeatable measurements of the bandgap energy of direct-gap semiconductors, in addition to providing insight to material quality via the Urbach energy, which quantifies the impact of sub-bandgap tail states, and the absorption knee amplitude. The model is simple and easily applied to any direct-gap semiconductor, enabling direct comparison between materials systems. The power law fit parameters provide insight to the energy dependence of the interband matrix element and the strength of the Coulomb enhancement of absorption. Finally, a well-defined absorption “knee” exists which may be calculated from the fitted model parameters and serves as a useful figure of merit for material quality.

Embodiments of the invention utilize a mathematical algorithm which is fit to measured optical absorption curves for direct bandgap semiconductors. It describes absorption (units of inverse cm) as a function of photon energy (eV) and is given in Equation 7A and Equation 7B above, where α_{g} is the absorption amplitude (inverse cm), hν is the photon energy, E_{g} is the bandgap energy, Eᵤ is the Urbach energy, and p is an energy-dependent power law term. Functionally, p is equal to p_{g}+(hν−E_{g})/Eₘ, where p_{g} is a constant power law term and Eₘ is a characteristic energy describing the above-bandgap absorption. In one embodiment, the model is fit using a least-squares fitting algorithm to measured absorption curves over a range spanning approximately 0.020 eV below the bandgap energy to 0.175 eV above the bandgap.

Certain embodiments and examples disclosed herein may reference particular fit ranges, however it is understood that the fit range may be subjective and that the presented examples are in no way limiting of the systems and methods disclosed herein. As would be understood by one skilled in the art, the fit range used will vary from material to material. In some embodiments, the fit range includes data points at several times the Urbach energy (Eₙ) below the bandgap energy, and data points up to about 0.2 eV above the bandgap energy. In various embodiments, a lower bound of a suitable fit range may be 0.02 eV below the bandgap energy, 0.03 eV below the bandgap energy, 0.04 eV below the bandgap energy, 0.05 eV below the bandgap energy, two times the material's Eᵤ, below the bandgap energy, three times the material's Eᵤ, below the bandgap energy, four times the material's Eᵤ, below the bandgap energy, five times the material's Eᵤ, below the bandgap energy, or any other suitable lower bound. In some embodiments, an upper bound of a suitable fit range may be 0.05 eV above the bandgap energy, 0.1 eV above the bandgap energy, 0.15 eV above the bandgap energy, 0.175 eV above the bandgap energy, 0.2 eV above the bandgap energy, 0.225 eV above the bandgap energy, 0.25 eV above the bandgap energy, 0.3 eV above the bandgap energy, 0.4 eV above the bandgap energy, or any suitable upper bound. In some embodiments, some points within the disclosed fit range may be excluded from the fit, for example to omit higher energy features not included in the disclosed models of the fundamental absorption edge.

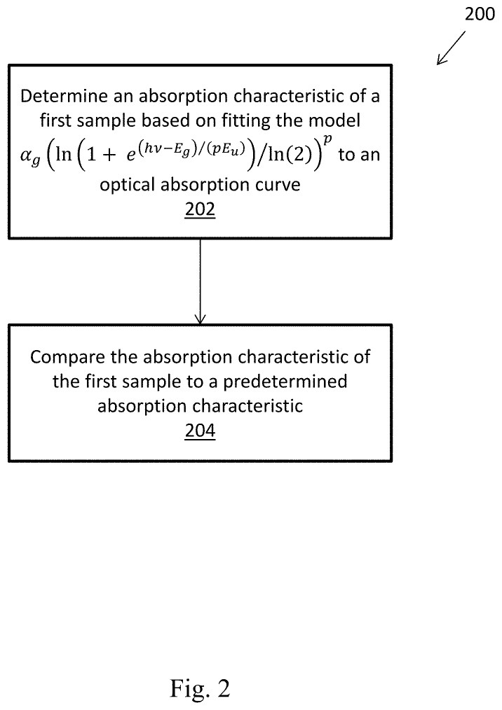

With reference now to FIG. 2, a method 200 for determining the composition of direct-gap semiconductors is shown according to one embodiment. The method includes the steps of (1) determining an absorption characteristic of a first sample based on fitting the model α_{g}(ln(1+e^{(hν-E}^{_{g}}^{)/(pE}^{ᵤ}⁾)/ln(2))^{p} to an optical absorption curve 202, and (2) comparing the absorption characteristic of the first sample to a predetermined absorption characteristic 204. In one embodiment, the model is fit using a least-squares fitting algorithm to measured optical absorption curves over a fit range. Accordingly, embodiments of the invention can be used to determine the composition of direct-gap semiconductors by comparing the absorption characteristics of a sample of unknown composition against those of a sample of known composition. In particular, the bandgap energy is strongly composition dependent. Embodiments of the invention provide highly accurate and repeatable measurements of bandgap energy, which can be used to determine composition. In one embodiment, the device is configured to calculate the composition of a sample comprising only a single material. In one embodiment, the device is configured to calculate the composition of a sample comprising more than one material, for example an alloy.

Embodiments of the invention are directed to a system or method for determining the composition of a material having unknown composition, based on the measured temperature of the material and the bandgap energy. The temperature may be measured directly, for example using a thermometer, thermal couple, or the like. In some embodiments, where measurements are performed at room temperature, the sample temperature may be assumed to be equal to that of the environment, for example between 295 K and 297 K for typical laboratory environments.

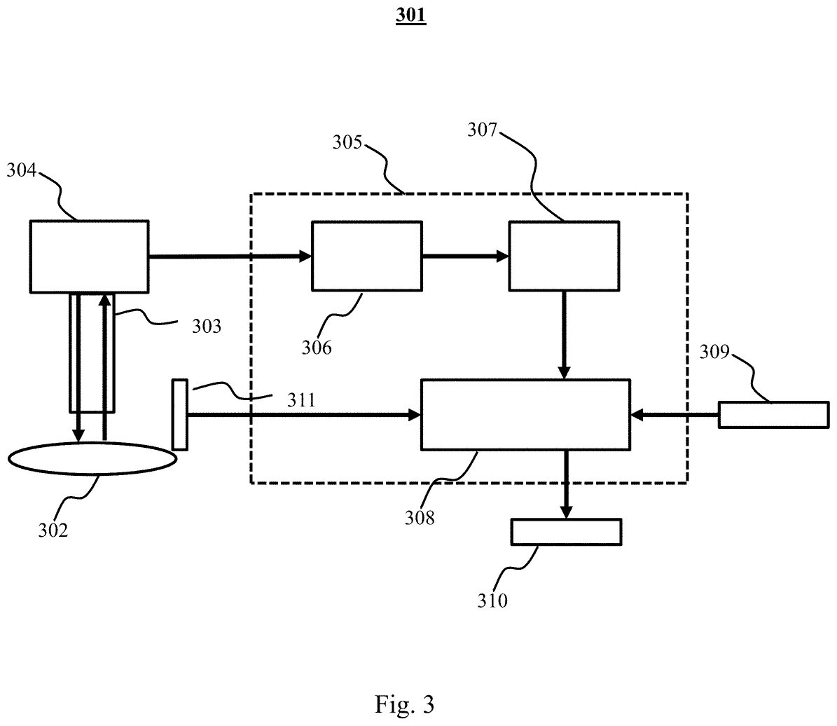

With reference now to FIG. 3, an exemplary embodiment of the invention is shown, implemented as a system for determining the composition of a sample. In the depicted embodiment 301, the sample under investigation 302 is a semiconductor or other material. A temperature sensor 311 is positioned on or near sample 302 in order to record the temperature of the material. A spectroscopic device 304 is used to determine the optical constants of the sample 302, passing through an optical coupling medium 303. The spectroscopic device 304 may be any suitable spectroscopic device, including but not limited to a broadband optical spectrometer, a spectroscopic ellipsometry device, or a reflectance or transmittance spectroscopy device. In some embodiments multiple spectroscopic devices may be used. The optical coupling medium 303 may similarly be any suitable optical coupling medium, including but not limited to free space, air, fiber optics, an optical coupling gel, or the like. The temperature sensor 311 may be a thermometer, thermal couple, optical thermometer, or any other suitable temperature measuring device. In some embodiments, the temperature sensor may be situated elsewhere in the room in which the measurements are taking place, and the temperature of the sample 302 may be inferred from the ambient temperature in the room.

The optical constants of the sample 302 may be calculated by a computing device 305 including for example an acquisition engine 306 communicatively connected to spectroscopic device 304. The acquisition engine 306 may be configured to receive data from spectroscopic device 304 either as calculated values or as measured primitives from which the optical constants may be calculated. Optical constants that may be obtained by the acquisition engine include, but are not limited to, Absorption (α), the extinction coefficient (κ), or the imaginary dielectric constant (ε₂). The computing system 305 may then use the measured constants to generate a fitted bandgap energy plot, using the equation α_{g} (ln(1+e^{(hν-E}^{_{g}}^{)/(pE}^{ᵤ}⁾)/ln(2))^{p}, where p=p_{g}+(hν−E_{g})/Eₘ in approximation engine 307. Finally, composition approximation engine 308 calculates an estimated output sample composition 310 from the fitted bandgap energy plot generated from approximation engine 307, the temperature measured by temperature sensor 302, and a temperature-dependent bandgap bowing model 309. The bandgap bowing model 309 may be obtained for example from literature.

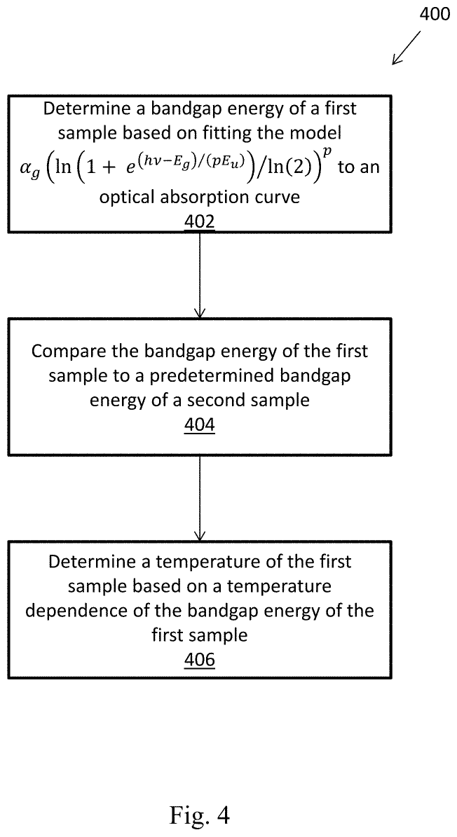

Further, embodiments of the invention can be used as an optical thermometer, as the bandgap energy is also temperature dependent. If the temperature dependence of the bandgap energy of a sample material is known, then measurements of the bandgap energy can determine the sample's temperature. With reference now to FIG. 4, a method 400 for determining a temperature of a direct-gap semiconductor is shown according to one embodiment. The method includes the steps of determining a bandgap energy of a first sample based on fitting the model α_{g} (ln(1+e^{(hν-E}^{_{g}}^{)/(pE}^{ᵤ}⁾)/ln(2))^{p} to an optical absorption curve 402, comparing the bandgap energy of the first sample to a predetermined bandgap energy of a second sample 404, and determining a temperature of the first sample based on a temperature dependence of the bandgap energy of the first sample 406.

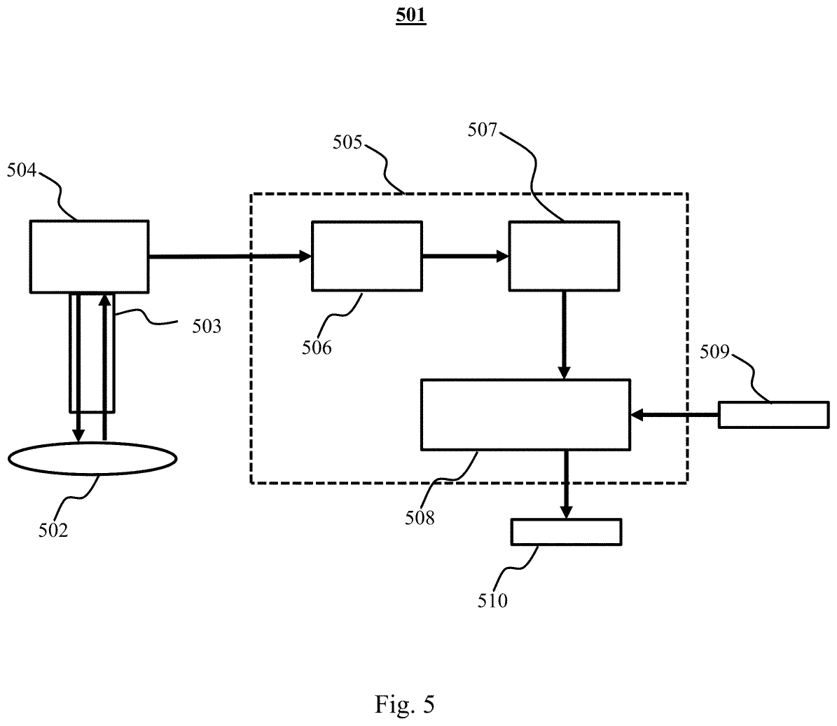

With reference now to FIG. 5, an exemplary embodiment of the invention is shown, implemented as an optical thermometer. In the depicted embodiment 501, the sample under investigation 502 is a semiconductor or other material whose composition is known. A spectroscopic device 504 is used to determine the optical constants of the sample 502, passing through an optical coupling medium 503. The spectroscopic device 504 may be any suitable spectroscopic device, including but not limited to a broadband optical spectrometer, a spectroscopic ellipsometry device, or a reflectance or transmittance spectroscopy device. In some embodiments multiple spectroscopic devices may be used. The optical coupling medium 503 may similarly be any suitable optical coupling medium, including but not limited to free space, air, fiber optics, an optical coupling gel, or the like.

The optical constants of the sample 502 may be calculated by a computing device 505 including for example an acquisition engine 506 communicatively connected to spectroscopic device 504. The acquisition engine 506 may be configured to receive data from spectroscopic device 504 either as calculated values or as measured primitives from which the optical constants may be calculated. The computing system 505 may then use the measured constants to generate a fitted bandgap energy plot, using the equation α_{g} (ln(1+e^{(hν-E}^{_{g}}^{)/(pE}^{ᵤ}⁾)/ln(2))^{p}, where p=p_{g}+(hν−E_{g})/Eₘ in approximation engine 507. Finally, temperature approximation engine 508 calculates an output sample temperature 510 from the fitted bandgap energy plot generated from approximation engine 507 and a temperature-dependent bandgap bowing model 509. The bandgap bowing model 509 may be obtained for example from literature.

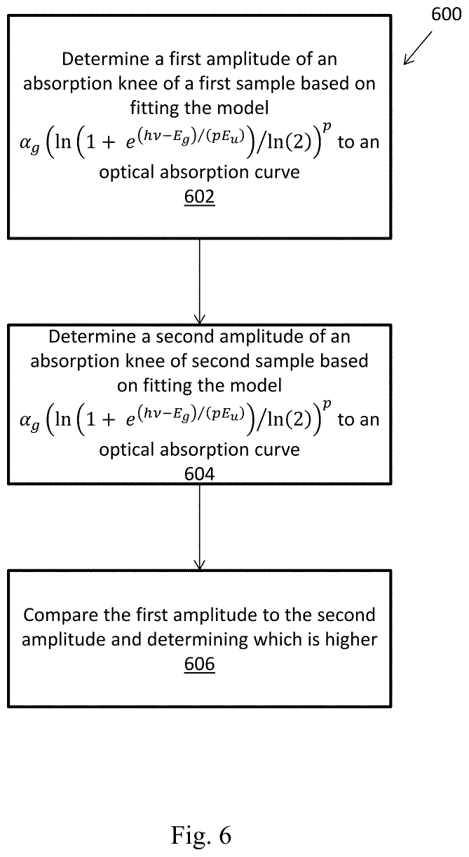

Embodiments of the invention can be used to directly compare optical quality of sample materials through the amplitude of the absorption knee. Higher optical quality samples will exhibit higher amplitude at the absorption knee. With reference now to FIG. 6, a method 600 for characterizing optical quality is shown according to one embodiment. The method 600 includes the steps of (1) determining a first amplitude of an absorption knee of a first sample based on fitting the model α_{g} (ln(1+e^{(hν-E}^{_{g}}^{)/(pE}^{ᵤ}⁾)/ln(2))^{p} to an optical absorption curve 602, (2) determining a second amplitude of an absorption knee of second sample based on fitting the model α_{g} (ln(1+e^{(hν-E}^{_{g}}^{)/(pE}^{ᵤ}⁾)/ln(2))^{p} to an optical absorption curve 604, and (3) comparing the first amplitude to the second amplitude and determining which is higher 606.

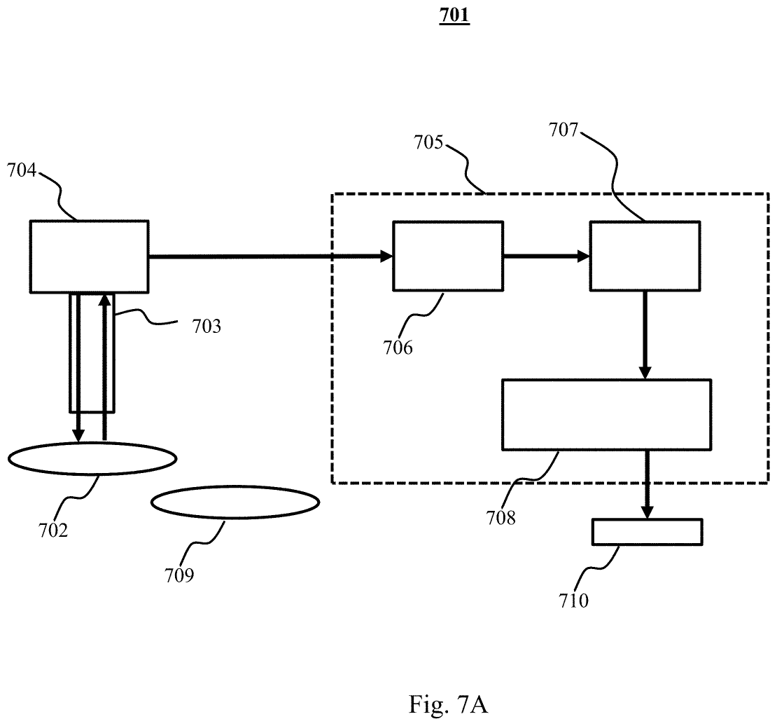

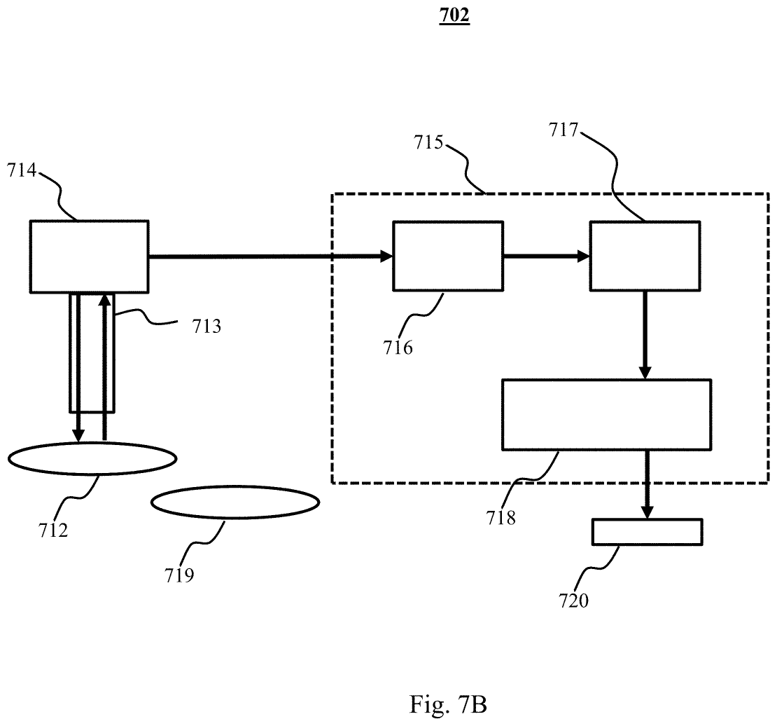

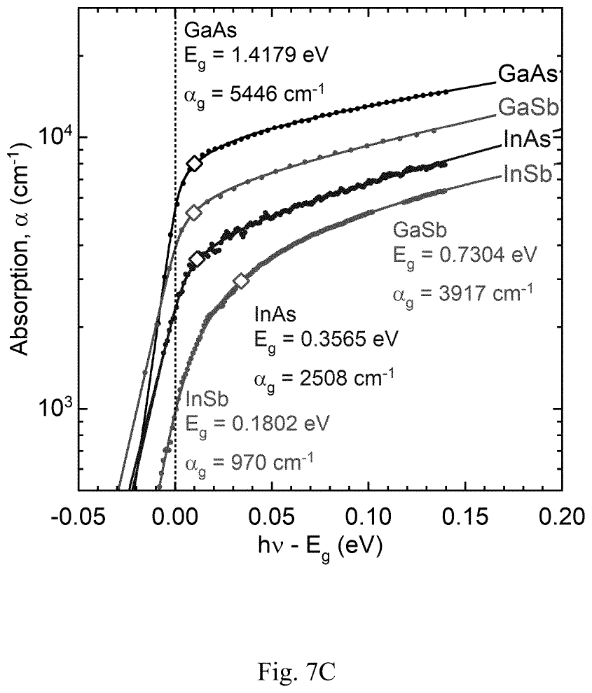

With reference now to FIG. 7A, an exemplary embodiment of the present invention is shown, implemented as a system 701 for comparing the optical quality of a first sample 702 and a reference sample 709. The sample under investigation 702 is a semiconductor or other material whose temperature and composition is known. A spectroscopic device 704 is used to determine the optical constants of the sample 702, passing through an optical coupling medium 703. The spectroscopic device 704 may be any suitable spectroscopic device, including but not limited to a broadband optical spectrometer, a spectroscopic ellipsometry device, or a reflectance or transmittance spectroscopy device. In some embodiments multiple spectroscopic devices may be used. The optical coupling medium 703 may similarly be any suitable optical coupling medium, including but not limited to free space, air, fiber optics, an optical coupling gel, or the like.

The optical constants of the sample 702 may be calculated by a computing device 705 including for example an acquisition engine 706 communicatively connected to spectroscopic device 704. The acquisition engine 706 may be configured to receive data from spectroscopic device 704 either as calculated values or as measured primitives from which the optical constants may be calculated. The computing system 705 may then use the measured constants to generate a fitted bandgap energy plot, using the equation α_{g} (ln(1+e^{(hν-E}^{_{g}}^{)/(pE}^{ᵤ}⁾)/ln(2))^{p}, where p=p_{g}+(hν−E_{g})/Eₘ in approximation engine 707. A second fitted bandgap energy plot may then be generated using corresponding constants from the reference sample 709. The amplitudes of the absorption knees of the two fitted plots may then be compared to determine quantitatively which of the samples 702 or 709 is of higher optical quality in output step 710. In certain embodiments, more than two samples are evaluated and ranked. In some embodiments, a system 701 includes a display or other indication means for indicating to a user the results of the calculations.

With reference now to FIG. 7B, an exemplary embodiment of the present invention is shown, implemented as a system 711 for comparing the optical quality as quantified by the Urbach energy parameter of a first sample 712 and a reference sample 719. The sample under investigation 712 is a semiconductor or other material whose temperature and composition is known. A spectroscopic device 714 is used to determine the optical constants of the sample 712, passing through an optical coupling medium 713. The spectroscopic device 714 may be any suitable spectroscopic device, including but not limited to a broadband optical spectrometer, a spectroscopic ellipsometry device, or a reflectance or transmittance spectroscopy device. In some embodiments multiple spectroscopic devices may be used. The optical coupling medium 713 may similarly be any suitable optical coupling medium, including but not limited to free space, air, fiber optics, an optical coupling gel, or the like.

The optical constants of the sample 712 may be calculated by a computing device 715 including for example an acquisition engine 716 communicatively connected to spectroscopic device 714. The acquisition engine 716 may be configured to receive data from spectroscopic device 714 either as calculated values or as measured primitives from which the optical constants may be calculated. The computing system 715 may then use the measured constants to generate a fitted bandgap energy plot, using the equation α_{g} (ln(1+e^{(hν-E}^{_{g}}^{)/(pE}^{ᵤ}⁾)/ln(2))^{p}, where p=p_{g}+(hν−E_{g})/Eₘ in approximation engine 717. A second fitted bandgap energy plot may then be generated using corresponding constants from the reference sample 719. The Urbach energy parameters of the two fitted plots may then be compared to determine quantitatively which of the samples 712 or 719 is of higher optical quality in output step 720. In some embodiments, a smaller value of the Urbach energy is preferred for device performance and indicates higher material and optical quality. In certain embodiments, more than two samples are evaluated and ranked. In some embodiments, a system 711 includes a display or other indication means for indicating to a user the results of the calculations.

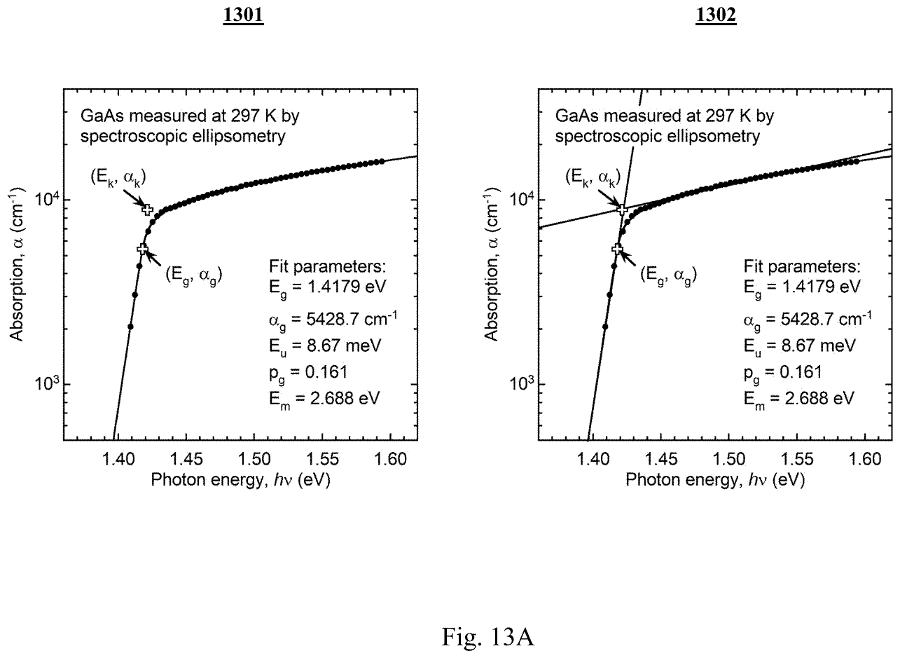

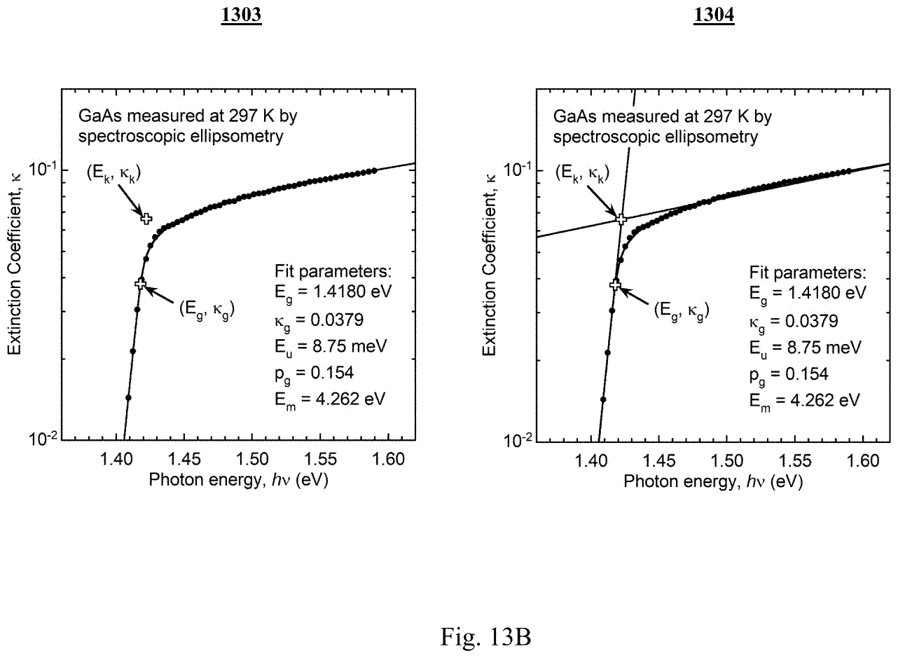

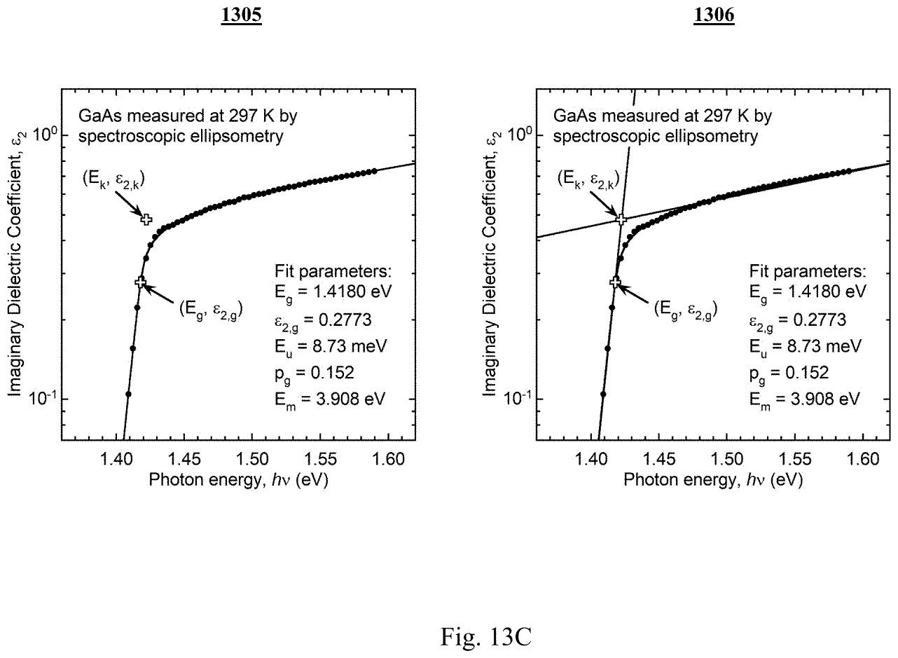

Exemplary fit models and corresponding absorption knees are shown in FIGS. 13A-13C, described further in the Experimental Examples below.

### EXPERIMENTAL EXAMPLES

The invention is now described with reference to the following Examples. These Examples are provided for the purpose of illustration only and the invention should in no way be construed as being limited to these Examples, but rather should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore, specifically point out the preferred embodiments of the present invention, and are not to be construed as limiting in any way the remainder of the disclosure.

### Experiment #1

The fundamental absorption-edge of semi-insulating GaAs and unintentionally doped GaSb, InAs, and InSb was investigated using spectroscopic ellipsometry. The measurements were performed on commercially available III-V wafers. The material specifications for resistivity, Hall mobility, and carrier concentration supplied by the manufacture are summarized in Table 1. The carrier concentrations were well below the conduction and valence band effective density of states N_{c} and N_{ν} at room temperature. Therefore the material was not degenerate and band filling effects such as the Moss-Burstein shift were negligible. The absorption measurements were performed on three separate GaAs samples A, B, and C to assess the reproducibility of the measurement technique and modeling work.

Table 1 below shows the physical and electrical characteristics of III-V substrates studied by ellipsometry. Values were obtained from wafer datasheets.

TABLE 1

| | | | | | Hall | Carrier |
|---|---|---|---|---|---|---|
| | | | Thickness | Resistivity | mobility | concentration |
| Material | Sample | Type | (μm) | (Ω · cm) | (cm²V⁻¹s⁻¹) | (cm⁻³) |
| GaAs | A | Semi- | 500 | 2 × 10⁸ | 5500 | 5 × 10⁶ |
| | B | insulating | 350 | 2 × 10⁸ | 5400 | 6 × 10⁶ |
| | C | | 350 | 2 × 10⁸ | 5400 | 6 × 10⁶ |
| GaSb | — | Undoped | 500 | 7 × 10⁻² | 700 | 1 × 10¹⁷ |
| | | (p-type) | | | | |
| InAs | — | Undoped | 500 | 1 × 10⁻² | 2.5 × 10⁴ | 2 × 10¹⁶ |
| | | (n-type) | | | | |
| InSb | — | Undoped | 640 | 6 × 10⁻² | 5.0 × 10⁵ | 2 × 10¹⁴ |
| | | (n-type) | | | | |

The spectroscopic ellipsometry measurements of GaAs and GaSb were performed using a J. A. Woollam VASE spectroscopic ellipsometer that covered 0.39 to 6.42 eV (193 to 3200 nm wavelength). Measurements of InAs and InSb were performed using a J. A. Woollam IR-VASE ellipsometer that covered 0.04 to 0.73 eV (1.7 to 30 μm). All measurements were performed at room temperature (297 K) using four incident angles (68°, 72°, 76°, and 80°) with a spectral resolution of 3.9 nm (6.3 meV for GaAs and 1.7 meV for GaSb) for the VASE measurements and 16 cm′ (2.0 meV for InAs and InSb) for the IR-VASE measurements. Because the wafers were transparent below the bandgap energy, reflection from the backside of the wafer resulted in the collection of spurious depolarized light at the detector. Therefore, the wafer backsides were roughened sequentially with 320 and 400 grit sandpaper to diffusely scatter the backside reflections. After backside roughening, the depolarization was less than 2%.

The WVASE software was used to obtain the optical constants of III-V wafers from the measured ellipsometry parameters W and A. The ellipsometry optical model employed two layers, a surface oxide layer and the III-V layer. The thickness of the wafers ranged from 350 to 640 μm and was treated as infinite when analyzing ellipsometry data. This assumption was justified as light that reaches the backside of the substrate was diffusely scattered. Optical constants of the oxide layers and the initial values of optical constants of the III-V substrates were provided by the WVASE software library. Because the optical constants for InSb oxide were not available, the InSb native oxide was modeled using the GaSb oxide optical constants.

The best fit thickness of the oxide layers is shown in Table 2 below. The optical constants were determined using the wavelength-by-wavelength method of analysis, which provided raw data that was not distorted by any mathematical modeling of the optical constants.

The Kramers-Kronig consistency of the optical constants was verified by repeating the fits using a generalized oscillator; the optical constants derived from the wavelength-by-wavelength fitting and generalized oscillator model agreed to within less than 1% over the entire wavelength range.

TABLE 2

| | Material | | | | | |
|---|---|---|---|---|---|---|
| | GaAs | | | | | |
| Sample | A | B | C | GaSb | InAs | InSb |
| Oxide thickness (nm) | 2.015 | 1.814 | 2.100 | 6.475 | 3.457 | 2.473 |

The measured absorption spectra for semi-insulating GaAs sample A and undoped GaSb, InAs, and InSb are presented in FIG. 7C as a function of photon energy less bandgap energy, which aligns the absorption edges for comparison. The absorption model in Equation 7A and Equation 7B (solid curve) was fit to the absorption data (solid circles). The fit range is from 140 meV above the bandgap down to an extinction coefficient of k=αhc/(4πhν)=0.014 below the bandgap, which was the sensitivity limit of the ellipsometric measurement. The least squares fit analysis assumes that the uncertainty in the value of each data point is proportional to its value, which results in a proportionally weighted fit to the entire data set. The results were highly reproducible with a standard deviation of 0.2 meV in the measured bandgap energy for the three GaAs samples. The best fit values for parameters α₉, E₉, Eᵤ, p₉, and Eₘ are summarized in Table 3, along with the absorption coefficient knee values Eₖ and αₖ identified from the minimum of radius of curvature for α=0.100 eV; see Equation 10. The energy scaling parameter a is selected at 40% of the full-scale range of −0.05 to 0.20 eV in FIG. 7C to coincide with the visual roll-over point observed on this energy scale. The values in Table 3 are reported to the significant level of precision necessary to illustrate the reproducibility of the GaAs measurements and to accurately reproduce the model parameters and curves.

With reference to FIG. 7C, a graph of the absorption coefficient α as a function of photon energy relative to the bandgap hν−E₉ for semi-insulating GaAs sample A and undoped GaSb, InAs, and InSb substrates is shown. Measured data is shown as solid circles. The solid lines are fits of the absorption model in Equation 7 to the data. The best fit parameters for bandgap energy E₉ and absorption coefficient α₉ are shown for each curve. The position of the knee in the spectrum is indicated by the open diamonds.

TABLE 3

| | GaAs | | | | | |
|---|---|---|---|---|---|---|
| | A | B | C | GaSb | InAs | InSb |
| α_{g} (cm⁻¹) | 5446 | 5427 | 5480 | 3917 | 2508 | 970 |
| E_{g} (eV) | 1.4179 | 1.4177 | 1.4183 | 0.7304 | 0.3565 | 0.1802 |
| Eᵤ (meV) | 8.69 | 8.66 | 8.74 | 13.98 | 14.05 | 10.67 |
| p_{g} | 0.1580 | 0.1583 | 0.1584 | 0.1613 | 0.1929 | 0.4948 |
| Eₘ (eV) | 2.541 | 2.472 | 2.529 | 1.501 | 1.190 | 4.332 |
| Eₖ (eV) | 1.4279 | 1.4277 | 1.4283 | 0.7401 | 0.3677 | 0.2142 |
| αₖ (cm⁻¹) | 8014 | 7921 | 7990 | 5286 | 3568 | 2958 |

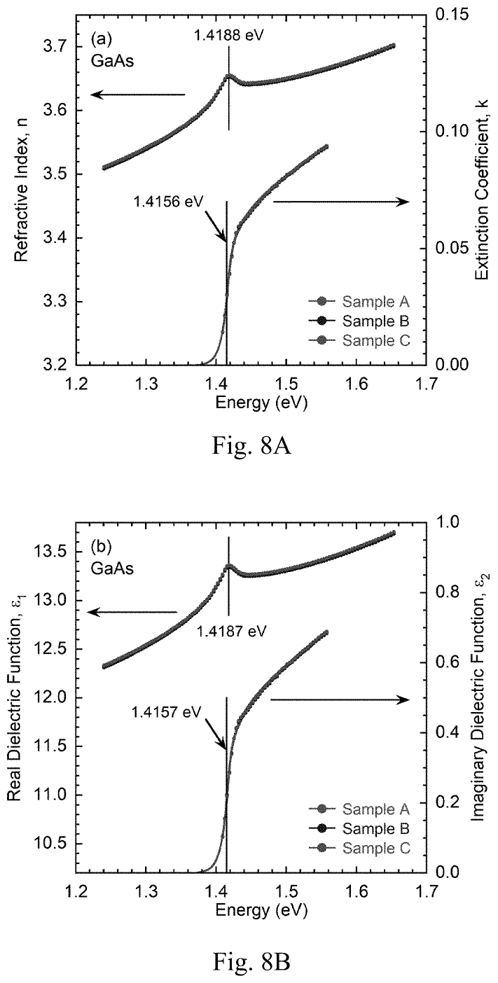

The optical constants n and k, and E₁ and E₂, are shown for the three semi-insulating GaAs samples in FIG. 8A and FIG. 8B. The first derivative maxima of k and ε₂, and the maxima of the n and ε₁, are shown by vertical lines and indicated numerically. The location of the maxima was precisely determined by interpolating the data in the region of the peak with a Gaussian function, where the peak location was given by the best fit value. Detailed sensitivity analysis showed that the resulting precision of the discrete numerical calculation of the first derivative maximum was better than 0.02 meV.

FIG. 8A shows the complex index of refraction and FIG. 8B shows the complex dielectric function for three different semi-insulating GaAs samples measured by spectroscopic ellipsometry. The peak value of the real parts n and ε₁, and the first derivative maximum of the imaginary parts k and ε₂, are indicated by vertical lines. The solid curves are fits of the model in Equation 7 to the k and ε₂ data over the photon energy range 140 meV above the bandgap down to an extinction coefficient of k=0.014 below the bandgap (1.4091-1.5579 eV).

The GaAs bandgap energy was estimated by i) fitting the absorption model in Equation 7 to a, k, and ε₂, ii) finding the first derivative maximum of α, k, and ε₂, and iii) finding the peak values of n and ε₁, shown in Table 4 below. There was excellent agreement between the three GaAs samples with the average and standard deviation of the values of the three samples shown in the right-hand column.

TABLE 4

| | | | | Average ± |
|---|---|---|---|---|
| | Sample A | Sample B | Sample C | Standard Deviation |
| | (eV) | (eV) | (eV) | (eV) |
| maximum of 1^{st} | 1.4157 | 1.4156 | 1.4158 | 1.4157 ± 0.00008 |
| derivative of ∈₂ | | | | |
| maximum of 1^{st} | 1.4157 | 1.4156 | 1.4158 | 1.4157 ± 0.00008 |
| derivative of k | | | | |
| maximum of 1^{st} | 1.4156 | 1.4155 | 1.4157 | 1.4156 ± 0.00008 |
| derivative of α | | | | |
| maximum of ∈₁ | 1.4187 | 1.4186 | 1.4188 | 1.4187 ± 0.00012 |
| maximum of n | 1.4188 | 1.4186 | 1.4189 | 1.4188 ± 0.00012 |

| | | | | Average ± |
|---|---|---|---|---|
| | Sample A | Sample B | Sample C | Standard Deviation |
| absorption coefficient | | | | |
| α fit to model | | | | |
| Amplitude α_{g} (cm⁻¹) | 5446 | 5427 | 5480 | 5451 ± 22 |
| E_{g} (eV) | 1.4179 | 1.4177 | 1.4183 | 1.4180 ± 0.0002 |
| Eᵤ (meV) | 8.69 | 8.66 | 8.74 | 8.70 ± 0.03 |
| p_{g} | 0.1580 | 0.1583 | 0.1584 | 0.1582 ± 0.0002 |
| Eₘ (eV) | 2.54 | 2.47 | 2.53 | 2.51 ± 0.03 |
| extinction coefficient | | | | |
| k fit to model | | | | |
| Amplitude k_{g} | 0.0383 | 0.0380 | 0.0384 | 0.0382 ± 0.0002 |
| E_{g} (eV) | 1.4181 | 1.4180 | 1.4183 | 1.4181 ± 0.0001 |
| Eᵤ (meV) | 8.81 | 8.75 | 8.84 | 8.80 ± 0.04 |
| p_{g} | 0.1500 | 0.1507 | 0.1507 | 0.1505 ± 0.0003 |
| Eₘ (eV) | 3.91 | 3.76 | 3.89 | 3.85 ± 0.07 |
| imaginary dielectric | | | | |
| function ∈₂ fit to model | | | | |
| Amplitude ∈_{2, g} | 0.280 | 0.278 | 0.281 | 0.280 ± 0.001 |
| E_{g} (eV) | 0.14181 | 0.14180 | 0.14183 | 1.4181 ± 0.0001 |
| Eᵤ (meV) | 8.79 | 8.72 | 8.82 | 8.78 ± 0.04 |
| p_{g} | 0.1478 | 0.1485 | 0.1485 | 0.1483 ± 0.0003 |
| Eₘ (eV) | 3.62 | 3.50 | 3.61 | 3.58 ± 0.06 |

Table 4 above shows the GaAs bandgap energy determined by first derivative maximum of extinction coefficient k, absorption coefficient α, and imaginary dielectric function E₂. Also shown are bandgap energies determined from the maximum values of refractive index n and real dielectric function ε₁. The model parameters for α, k, and ε₂ are summarized for each GaAs sample in the lower portion of the table. The model fits were performed over the same photon energy range as in FIG. 7C.

Agreement was observed for the best fit model (Equation 7) parameters for the bandgap energy E_{g} and the Urbach energy Eᵤ obtained from the three optical constants α, k, and ε₂. Agreement was also observed for the first derivative maximum obtained from the three optical constants α, k, and £₂, although the first derivative maximum values were about 2 meV less than the bandgap value determined from the fit of the model to the data. The best fit power law p_{g} values were within 4% across the 3 sets of optical constants. The characteristic energy Eₘ was larger for the optical constants k and ε₂, indicating a weaker energy dependence above the bandgap compared to the absorption coefficient α, as indicated in the relations of Equation 11 where k and E₂ are proportional to α/hν.

### DISCUSSION

The absorption amplitude was observed to increase with bandgap energy and was analyzed at the bandgap energy using the product of the optical density of states, the transition strength, and the Coulomb enhancement factor in Equation 2, Equation 3, and Equation 6, where

$${α}_{A} = {lim}_{h v \to {E}_{g}} ρ ( h v ) S ( h v ) F ( h v ) = \frac{4 \sqrt{2} {π}^{2} {e}^{2} \sqrt{{m}_{e}}}{c {ɛ}_{0} {h}^{2}} \cdot \sqrt{{E}_{e x}} {( \frac{{m}_{c} {m}_{v}}{{m}_{c} + {m}_{v}} )}^{3 / 2} \frac{{S}_{0} ( {E}_{g} )}{n ( {E}_{g} )} \qquad Equation 13$$

The exciton binding energy Eₑₓ is a product of the band structure and can be expressed to first order in terms of the effective mass as

$${E}_{e x} = \frac{{m}_{c} {m}_{v}}{{m}_{c} + {m}_{v}} {R}_{H} / {ɛ}^{2} , \qquad Equation 14$$

where ε is the dimensionless static dielectric constant and R_{H}=13.6 eV is the hydrogen Ryberg constant. The four terms on the right-hand side of Equation 13 vary with bandgap energy and their values and power law relation with bandgap energy are provided in Table 5 below.

Experimentally measured exciton binding energies from the literature were used in the calculation of Equation 13, as the values predicted by Equation 14 were significantly larger for the smaller bandgap materials.

TABLE 5

| | | | | | Power laws | |
|---|---|---|---|---|---|---|
| | GaAs | GaSb | InAs | InSb | vs E_{g} | $vs \frac{{m}_{c} {m}_{v}}{{m}_{c} + {m}_{v}}$ |
| Measured bandgap | 1.4179 | 0.7304 | 0.3552 | 0.1803 | 1 | 1.553 |
| energy E_{g} from Eq. 7 | | | | | | |
| model fit (eV) | | | | | | |
| Experimental exciton | 4.0 | 2.1 | 1.0 | 0.4 | 1.110 | 1.554 |
| binding energy Eₑₓ | | | | | | |
| values (meV) | | | | | | |
| Experimental static | 12.9 | 15.7 | 15.2 | 16.8 | −0.111 | −0.157 |
| dielectric constant ε | | | | | | |
| Experimental reduced | 0.0595 | 0.0364 | 0.0245 | 0.0131 | 0.717 | 1 |
| $effective mass \frac{{m}_{c} {m}_{v}}{{m}_{c} + {m}_{v}}$ | | | | | | |
| Optical density of states | 0.0145 | 0.0069 | 0.0038 | 0.0015 | 1.076 | 3/2 |
| effective mass | | | | | | |
| ${( \frac{{m}_{c} {m}_{v}}{{m}_{c} + {m}_{v}} )}^{3 / 2}$ | | | | | | |
| Theoretical transition | 18.1 | 33.8 | 60.0 | 134.8 | −0.950 | −1.415 |
| strength values S₀ (E_{g}) | | | | | | |
| Measured index of | 3.632 | 3.990 | 3.607 | 3.929 | −0.019 | −0.079 |
| refraction values n (E_{g}) | | | | | | |
| Momentum matrix | 25.6 | 24.7 | 21.3 | 24.3 | 0.050 | 0.195 |
| $element \frac{2}{{m}_{e}} {\vert 〈 {ψ}_{h} \vert p \vert {ψ}_{h} 〉 \vert}^{2}$ | | | | | | |
| (eV) | | | | | | |
| Calculated absorption | | | | | | |
| amplitude (Equation 13) | 21423 | 12662 | 9466 | 4830 | 0.693 | 0.956 |
| α_{A} (cm⁻¹) | | | | | | |

Table 5 shows material parameters and calculated absorption amplitude at the bandgap energy. The power law relation of the parameters with bandgap energy and reduced effective mass are shown in the rightmost two columns.

The experimental values of the joint optical density of states effective mass, the exciton binding energy Eₑₓ, and the strength of the Coulomb interaction \sqrt{Eₑₓ} all increased with bandgap energy with power laws 1.08, 1.11, and 0.56 respectively. The transition strength S₀ decreased with bandgap energy with power law-0.95. The index of refraction was about 9% larger for the antimonides and did not significantly vary with bandgap energy. The momentum matrix element (2/mₑ)| [symbol] ₕ|p|ψₑ [symbol] |² in units of eV and the subsequent transition strength was determined from literature. The momentum matrix element at the F point did not significantly change with bandgap energy.

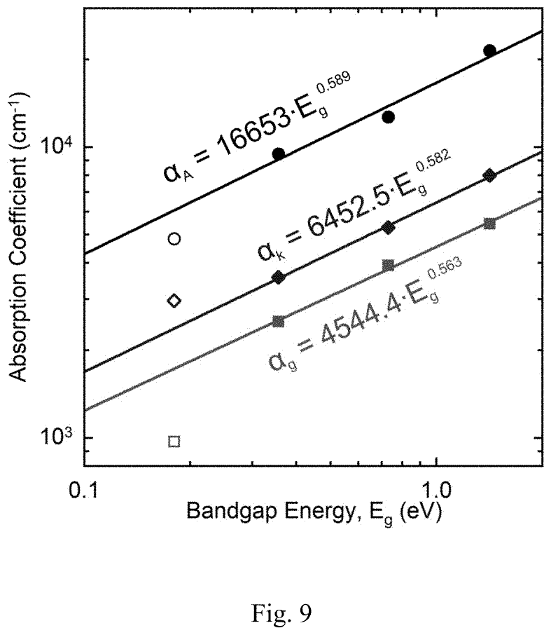

The theoretical absorption amplitude α_{A} (black circles) and the experimental absorption amplitudes α₉ (red squares) and absorption knee αₖ (blue diamonds) are compared in FIG. 9 for GaAs, GaSb, InAs, and InSb. The solid curves are fits of a power law to the results for GaAs, GaSb, and InAs (solid symbols), with the best fit expressions indicating a power law near 0.6 for all three measures of absorption strength. The values for InSb (open symbols) were excluded from the fit as the values for InSb did not consistently follow the bandgap dependence trend of the other three materials. The k·p perturbation method indicated a non-parabolic nature in the InSb conduction band, however this nonparabolicity only became a significant correction at about 0.2 eV above the fundamental bandgap energy. The energy range analyzed in this disclosure extends to 0.14 eV above the bandgap energy. The limited agreement between the InSb absorption amplitudes and the power law trend in FIG. 9 are attributed to a much weaker Coulomb interaction that resulted in a poorly defined knee in the spectrum rather than InSb band nonparabolicity.

With reference to FIG. 9, the calculated absorption amplitude α_{A} (black circles) and the experimental absorption amplitudes α₉ (red squares) and absorption knee αₖ (blue diamonds) are compared for GaAs, GaSb, InAs, and InSb. The solid curves are power law fits to the GaAs, GaSb, and InAs results (solid circles), with best fit expressions shown. The results for InSb (open symbols) were excluded from the fits.

The Kramers-Kronig dispersion relation between the real and imaginary parts of the optical constants specified that onset of absorption in the imaginary parts, k, or ε₂, is manifested as a peak in the real part, n or ε₁. This small peak in the real part of the optical constants is denoted as Δn and ΔE₁ and is given by Kramers-Kronig relation of the optical constants k and ε₂ evaluated over an integration range of hν₁=1.38 eV to hν₂=1.50 eV, with

$$\begin{matrix}Δ n ( hv ) = \frac{2}{π} 𝒫 {\int }_{{hv}_{1}}^{{hv}_{2}} \frac{k ( {hv}^{′} ) {hv}^{′}}{{( {hv}^{′} )}^{2} - {( hv )}^{2}} {dhv}^{′} & Equation 15 A \\ Δ {ɛ}_{1} ( hv ) = \frac{2}{π} 𝒫 {\int }_{{hv}_{1}}^{{hv}_{2}} \frac{{ɛ}_{2} ( {hv}^{′} ) {hv}^{′}}{{( {hv}^{′} )}^{2} - {( hv )}^{2}} {dhv}^{′} & Equation 15 B\end{matrix}$$

where [symbol] denotes the Cauchy principal value of the integral. The integration range of 1.38 eV to 1.50 eV was selected to yield the same amplitude of Δn as in the experiment. This integration range yielded an amplitude for Δε₁ that was within 5% of the experimental value. The experimental values for Δn and ΔE₁ were obtained from the measured data by subtracting off a linear background not attributed to the fundamental absorption edge, which was n=2.930+0.469·hν and ε₁=8.178+3.352·hν for GaAs. It was necessary to subtract the linear background as it resulted in a blue shift of the peak values that was not attributable to the fundamental bandgap. Decreasing the lower limit of integration below 1.38 eV had no effect on the amplitude or peak position of Δn and ΔE₁ due to the rapid decrease in optical absorption below the fundamental absorption edge. However, increasing the upper limit of integration above 1.50 eV increased the amplitude and slightly blue-shifted the peaks in relation to the bandgap energy, which was as much as 0.9 meV for an upper integration limit of 2.50 eV. The integration range of 1.38 eV to 1.50 eV was in agreement with other analyses performed in literature.

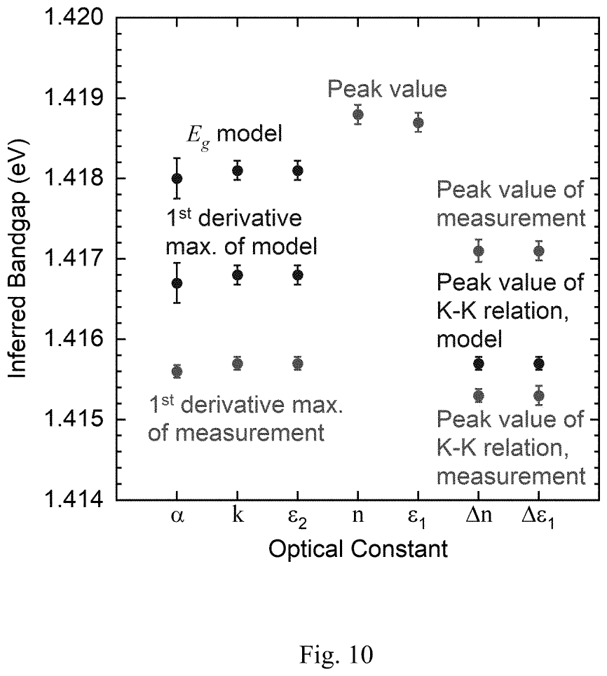

The semi-insulating GaAs bandgap energies at 297 K determined by the various methods discussed in this work are compared in FIG. 10. The values determined from the fit of the model in Equation 7 to the measured absorption data are indicated in blue and the values determined directly from the measured data are shown in red. The optical constants examined are listed on the horizontal axis, left to right: absorption coefficient α, extinction coefficient k, imaginary dielectric coefficient ε₂, refractive index n, real dielectric coefficient ε₁, refractive index change Δn, and real dielectric coefficient change ΔE₁. Error bars indicate the standard deviation over the three samples measured. The various methods agree within a few meV of each other. The peak values of n and ε₁ were blue shifted by about 2 meV compared to the peak values of Δn and ΔE₁, which were blue shifted by about 1 meV compared to their values calculated from the Kramers-Kronig relation using both the model (blue) and the measurements (red). The bandgap energy identified by the first derivative maximum of the absorption coefficient α, extinction coefficient k, and imaginary dielectric function ε₂ was red shifted by about 1 meV using the model (blue) and by about 2 meV using the measured data (red) compared to E₉ determined from the model.

With reference to FIG. 10, a comparison of GaAs bandgap energies at 297 K determined from the absorption edge model in Equation 7 (blue circles) and the measured data (red circles) for the various optical constants and analytical methods, including the positions of peak values and 1^{st} derivative maxima is shown. The error bars show the standard deviation in the measurements of three GaAs samples. The horizontal-axis labels, left to right, are absorption coefficient α, extinction coefficient k, imaginary dielectric coefficient ε₂, refractive index n, real dielectric coefficient ε₁, refractive index change Δn, and real dielectric coefficient change Δε₁.

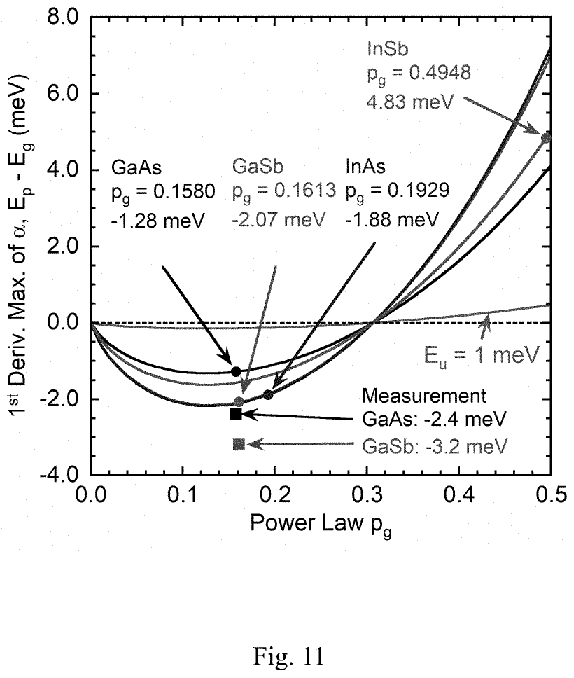

The energy position of the first derivative maximum Eₚ of the absorption model in Equation 7 as a function of the power law parameter p_{g} is shown in FIG. 11. The first derivative maximum shift relative to the model bandgap energy E_{g} is shown using the GaAs Urbach energy Eᵤ=8.70 meV, GaSb Eᵤ=13.98 meV, InAs Eᵤ=14.05 meV, InSb Eᵤ=10.67 meV, and a hypothetical Eᵤ=1.00 meV. In general the first derivative maximum of the absorption edge model does not occur exactly at the fit parameter E_{g} except in the specific cases where p_{g} is zero or 0.31 as illustrated in FIG. 11. In the case where there is little exponential broadening of the absorption edge, the Urbach energy becomes small, and the first derivative maximum energy approaches the bandgap energy E_{g} for all values of p_{g}, as illustrated by the grey curve. Relative to the bandgap parameter E_{g} the deviation of the first derivative maximum was less than one half of the Urbach energy Eᵤ, and was slightly blue shifted for InSb that has a weak Coulomb interaction and is slightly red shifted for the larger bandgap III-Vs where the Coulomb interaction is more pronounced. The numerical first derivative maxima determined directly from the data for GaAs (1.4156 eV) and for GaSb (0.7272 eV) are also shown in FIG. 11. The values are redshifted by approximately 1.1 meV with respect to the first derivative maximum of the absorption model.

With reference to FIG. 11, a comparison of the position of the first derivative maximum to the model parameter Eₚ−E_{g} as a function of power law p_{g} is shown for GaAs (black) with Urbach energy Eᵤ=8.70 meV, GaSb (green) with Eᵤ=13.98 meV, InAs (blue) with Eᵤ=14.05 meV, InSb (red) with Eᵤ=10.67 meV, and for Eᵤ=1 meV (grey). The analytical first derivative maxima of the model for each material is shown as solid circles. The numerical first derivative maxima obtained directly from the GaAs and GaSb data is shown as solid squares for comparison.

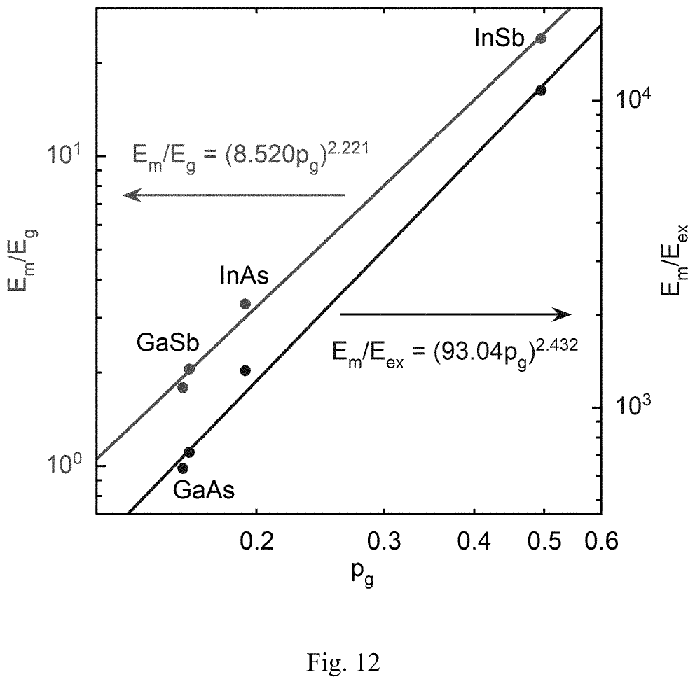

The ratio of the model parameters Eₘ/E_{g} as a function of p_{g} is shown in red in FIG. 12 for GaAs, GaSb, InAs, and InSb. The ratio of Eₘ/Eₑₓ as a function of p_{g}, where Eₑₓ is the exciton binding energy from Table 5, is shown in blue in FIG. 12 for comparison. These results illustrate that p_{g} and Eₘ/E_{g} are correlated with a power law relation of about 2.2 as shown by the best fit equation in red. The absorption coefficient, bandgap energy, and exciton binding energy all scale with reduced effective mass, m_{c}m_{ν}/(m_{c}+m_{ν}). Therefore the relation Eₘ/Eₑₓ versus p_{g} exhibits a similar power law of about 2.4. The power law p_{g} and the ratio Eₘ/E_{g} both decreased with increasing bandgap energy, reflecting the increasing strength of the Coulomb interaction between electrons and holes. As the bandgap energy decreased, the Coulomb enhancement of absorption became negligible for InSb. As a result the InSb absorption coefficient behaved like that predicted for a parabolic band density of states and a constant transition strength. Larger bandgap materials exhibit reduced dielectric screening by mobile charges due to their stronger atomic potentials, and hence the Coulomb interaction was more pronounced for GaAs, GaSb, and InAs.

With reference to FIG. 12, the ratio of the model parameters Eₘ/E_{g} (red) and Eₘ/Eₑₓ (blue) as a function of model parameter p_{g} are shown for GaAs, GaSb, InAs, and InSb. The power law relation for each is also shown.

The exciton binding energies in the III-V semiconductors examined in this example ranged from approximately 0.4 meV for InSb to 4.0 meV for GaAs, which were relatively small compared to the thermal energy of 25.6 meV at the 297 K measurement temperature. Nevertheless, an exciton absorption peak was typically observed in high-purity GaAs up to room temperature. However, the semi-insulating GaAs measured in this example had a very short carrier lifetime due to a high density of deep-levels in the material. Therefore an excitonic absorption peak was not observed in the spectroscopic ellipsometry measurements in this example, although the Coulomb interaction was clearly present in the onset of absorption of GaAs, GaSb, and InAs.

For small bandgap InSb where the Coulomb enhancement of absorption was weak, it was straightforward to interpret the model parameters p_{g}=0.495 and Eₘ=4.33 eV. In the absence of a Coulomb interaction, the power law reduces to the dispersion relation between energy and momentum determined by band structure near the fundamental bandgap. In the nearly free carrier approximation this yielded a value of one half corresponding to a parabolic band. Furthermore, the relatively large value of the characteristic energy Eₘ indicated that the optical transition strength S₀ was close to constant.

The Coulomb enhancement of absorption was significant for GaAs, GaSb, and InAs and complicated the physical interpretation of the model parameters p_{g} and Eₘ. Nevertheless, they provided insight to the relative strength of Coulomb interaction and the energy dependence of transition strength. The increase in the magnitude of the Coulomb interaction with bandgap was evident from the decrease in the power law p_{g} as the absorption at the bandgap energy was enhanced. Furthermore, a picture emerged where the photon energy dependence of the optical transition as a function of bandgap energy was clarified. The decrease in Eₘ/Eₑₓ with bandgap energy associated with the optical transition indicates that as the Coulomb interaction increased, the photon energy dependence changed from a constant transition strength (Equation 5C) for small bandgap InSb to a constant dipole matrix element (Equation 5B) for larger bandgap GaAs.

None of the experimental observations in these materials indicated that the momentum matrix element was independent of photon energy, which was expected to result in negative values for the characteristic energy Eₘ. However, in Table 5 the theoretical momentum matrix values at the F point were nearly constant across the materials examined, which is consistent with the experiment as illustrated by the similar power laws in the increase of absorption magnitude with bandgap energy observed in FIG. 9. Nevertheless, the fact that the momentum matrix element was nearly constant across bandgap energies does not necessarily imply that it should be independent of photon energy for interband optical transitions within a particular material.

A literature survey of the published values of the room-temperature (297 K) bandgap energy of GaAs found a range of 1.422 to 1.436 eV, with a widely accepted value of 1.424 eV. The model in Equation 7 used in this example identifies the 297 K GaAs bandgap energy at 1.418 eV, approximately 6 meV lower than the commonly-accepted value from literature. Existing studies identify the bandgap energy by backing out the Coulomb interaction from a measured feature in the optical constants or by extrapolating the below-bandgap Urbach edge to a known bandgap absorption coefficient. On the other hand, in this disclosure the bandgap is identified directly from onset of absorption in the measured optical constants, which may be better described as the optical bandgap.

When comparing the features in the GaAs optical constants measured in this example to those in the literature, the energy of the onset of absorption and the peak in the index of refraction were at the same energy positions. This indicates that any discrepancy was not due to experimental measurement differences, such as temperature or doping level, but instead was a result of how the bandgap was determined from the optical constants, such as how the onset of absorption was impacted by the Coulomb interaction. There is a distinction between the single-electron bandgap, a theoretical construct based on the assumption of empty conduction band that neglects many-body effects, and the optical bandgap energy that includes the effects of electron-electron interactions and electron-hole interactions, encompassing excitonic absorption and the Coulomb interaction. These effects result in a smaller optical bandgap than that predicted from the single-electron model.

The optical bandgap energy is the most relevant consideration in the description and design of optoelectronic devices, as it is the energy of the onset of absorption and emission that determines how devices perform. For example, the bandgap energy is generally described as the cutoff of absorption in photodetectors and photovoltaic solar cells and as the cutoff of emission from light emitting diodes.

Somewhat closer agreement was found between the GaSb, InAs, and InSb bandgap energies measured in this example and those reported in the literature. A literature survey finds 297 K bandgap energies ranging from 0.724 to 0.728 eV for GaSb, from 0.350 to 0.356 eV for InAs, and from 0.169 to 0.180 eV for InSb. The optical bandgap energies measured in this example were 0.730 eV, 0.357 eV, and 0.180 eV for GaSb, InAs, and InSb respectively, which were all on the upper end of the range measured in the literature. Many of these measurements were based on analysis of photoluminescence peak energy or extrapolations of absorption coefficients down to zero. There are complications in the extraction of optical bandgap energy using each of these various methods which can make it difficult to exactly compare the room temperature bandgap energy.

The absorption model presented is in principle applicable to any direct-gap semiconductor or material that exhibits an exponential absorption edge, such as III-V, II-VI, I-VII, and their alloys. Application to very small bandgap materials operating in the long-wave infrared would be subject to the typical challenges associated with narrow-bandgap materials, such as free carrier absorption and degenerate carrier levels. Furthermore, for materials with strong excitonic absorption, it would be necessary to add a term to capture the excitonic lineshape. This may become a significant effect for high purity materials with bandgaps wider than GaAs. Ionic materials and highly mismatched alloys are expected to exhibit a broader absorption edge and with a subsequent larger Urbach energy Eᵤ. Moreover, alloy-induced inhomogeneous broadening of the absorption edge will complicate the interpretation of the modeled bandgap energy.

### Conclusion

The intrinsic absorption edges of GaAs, GaSb, InAs, and InSb were examined using a model that was developed to describe and parameterize the experimentally observed features of the fundamental bandgap absorption edge, which include the optical bandgap energy E_{g}, the width of the Urbach tail Eᵤ, the impact of the Coulomb interaction on the absorption edge p_{g}, and the magnitude of the absorption coefficient at the bandgap cutoff α₉ and at the knee of the absorption spectrum αₖ. The Urbach parameter Eᵤ was determined from the exponential absorption edge below the bandgap and the optical bandgap parameter E₉ and absorption edge power law parameter p₉ were determined from the above-bandgap absorption. The room-temperature (297 K) values of the optical bandgap energy and Urbach parameter were 1.418 eV and 8.7 meV for GaAs, 0.730 eV and 14.0 meV for GaSb, 0.357 eV and 14.1 meV for InAs, and 0.180 eV and 10.7 meV for InSb. The GaAs optical bandgap energy determined from the absorption coefficient, extinction coefficient, and real part of the dielectric function agreed closely with the peak values of the refractive index and real dielectric function. The energy dependence of the optical absorption above the bandgap was observed to be most accurately described by the constant dipole matrix element approximation for GaAs where the Coulomb interaction was strong and by the constant transition strength approximation for InSb where the Coulomb interaction was weak.

### Experiment #2

With reference now to FIG. 13A, a sample of gallium arsenide (GaAs) measured at 297 K by spectroscopic ellipsometry (black circles). The corresponding fit of the absorption model α_{g}(ln(1+e^{(hν-E}^{_{g}}^{)/pE}^{ᵤ}⁾/ln(2))^{p} is shown to the data (black line). Two points of interest are identified by solid crosses: the amplitude α₉ at the bandgap energy E_{g}, and the absorption “knee” amplitude αₖ and energy Eₖ. The absorption knee provides a measure of optical quality which may be compared across materials systems. As shown in graph 1302, the absorption knee is calculated as the intersection between the two asymptotes of the roughly linear regions of the graph. Fit parameters in the absorption model are indicated on the figure.

The corresponding graphs of the extinction coefficient (K) and imaginary dielectric coefficient (ε₂) are shown in FIG. 13B and FIG. 13C, respectively.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

### REFERENCES

The following publications are each incorporated herein by reference in their entireties:
M. V. Kurik, “Urbach Rule”, Phys. Status Solidi A 8, 9 (1971).
S. R. Johnson and T. Tiedje, “Temperature dependence of the Urbach edge in GaAs”, J. Appl. Phys. 78, 5609 (1995).
M. Beaudoin, A. J. G. DeVries, S. R. Johnson, H. Laman, and T. Tiedje, “Optical absorption edge of semi-insulating GaAs and InP at high temperatures”, Appl. Phys. Lett. 70, 26 (1997).
V K Malyutenko and V I Chernyakhovsky, “Thermal emission of InAs induced by band tails”, Semicond. Sci. Technol. 9, 1047-1049 (1994).
R. J. Elliott, “Intensity of Optical Absorption by Excitons”, Phys. Rev. 108, 1384 (1957).
J. S. Blakemore, “Semiconducting and other major properties of gallium arsenide”, J. Appl. Phys. 53, R123 (1982).
Y. H. Lee, A. Chavez-Pirson, S. W. Koch, H. M. Gibbs, S. H. Park, J. Morhange, A. Jeffery, and N. Peyghambarian, “Room-temperature optical nonlinearities in GaAs”, Phys. Rev. Lett. 57, 2446 (1986).
P. T. Webster, N. A. Riordan, S. Liu, E. H. Steenbergen, R. A. Synowicki, Y.-H. Zhang, and S. R. Johnson, “Measurement of InAsSb bandgap energy and InAs/InAsSb band edge positions using spectroscopic ellipsometry and photoluminescence spectroscopy”, J. Appl. Phys. 118, 245706 (2015).
P. T. Webster, N. A. Riordan, S. Liu, E. H. Steenbergen, R. A. Synowicki, Y.-H. Zhang, and S. R. Johnson, “Absorption properties of type-II InAs/InAsSb superlattices measured by spectroscopic ellipsometry”, Appl. Phys. Lett. 106, 061907 (2015).
D. Souri and Z. E. Tahan, “A new method for the determination of optical band gap and the nature of optical transitions in semiconductors”, Appl. Phys. B 119, 273-279 (2015).
P. T. Webster, A. J. Shalindar, N. A. Riordan, C. Gogineni, H. Liang, A. R. Sharma, and S. R. Johnson, “Optical properties of InAsBi and optimal designs of lattice-matched and strain-balanced III-V semiconductor superlattices”, J. Appl. Phys. 119, 225701 (2016).
P. P. Paskov, “Optical absorption and refraction spectra in highly excited GaSb”, IEEE J. Quantum Elec. 30, 12 (1994).
A. R. Hassan, “On the estimation of matrix elements for optical transitions in semiconductors”, Optics Communications 98, 80-85 (1993).
W. B. Jackson, S. M. Kelso, C. C. Tsai, J. W. Allen, and S.-J. Oh, “Energy dependence of the optical matrix element in hydrogenated amorphous and crystalline silicon”, Phys. Rev. B 31, 5187 (1985).
M. Rohlfing and S. G. Louie, “Electron-Hole Excitations in Semiconductors and Insulators”, Phys. Rev. Lett. 81, 2312 (1998).
T. Ogawa and T. Takagahara, “Optical absorption and Sommerfeld factors of one-dimensional semiconductors: An exact treatment of excitonic effects”, Phys. Rev. B 44, 8138 (1991).
P. J. P. Tang, M. J. Pullin, and C. C. Phillips, “Binding energy of the free exciton in indium arsenide”, Phys. Rev. B 55, 7 (1996).
F. Stern, “Dispersion of the Index of Refraction Near the Absorption Edge of Semiconductors”, Phys. Rev. B 133, A1653 (1964).
J.-M. Jancu, R. Scholz, E. A. de Andrada e Silva, and G. C. La Rocca, “Atomistic spin-orbit coupling and k·p parameters in III-V semiconductors”, Phys. Rev. B 72, 193201 (2005).
M. W. Heller, and R. G. Hamerly, “Hole transport in gallium antimonide”, J. Appl. Phys. 57, 10, 4626 (1985).
F. P. Kesamanly, Yu. Matsev, D. N. Nasledov, L. A. Nikolaeva, M. N. Pivovarov, V. A. Skripkin, and Yu. I. Uvanov, Fiz. Tekhn. Polupr. 3, 8, p. 1182-1187 (1969).
W. Zawadski, “Electron transport phenomena in small-gap semiconductors”, Advances in Phys. 23, p. 435-522 (1974).
M. Merian and A. K. Bhattacharjee, “Momentum Matrix Elements in III-V Semiconductor Alloys”, Solid State Communications 55, 12, p. 1071-1073 (1985).
C. Hermann and C. Weisbuch, “k ?·p ? perturbation theory in III-V compounds and alloys: a reexamination”, Phys. Rev. B 15, 2, p. 823-833 (1977).
P. Pfeffer and W. Zawadzki, “Five-level k·p model for the conduction and valence bands of GaAs and InP”, Phys. Rev. B 53, 19, p. 12813-12828 (1996).
Y. J. Jung, M. K. Park, S. I. Tae, K. H. Lee, and H. J. Lee, “Electron transport and energy-band structure of InSb”, J. Appl. Phys. 69, 3109 (1991).
D. S. Chemla, D. A. B. Miller, and P. W. Smith, “Nonlinear Optical Properties of Multiple Quantum Well Structures for Optical Signal Processing”, Semiconductors and Semimetals Vol 24, 279 (1987).
M. B. Panish and H. C. Casey, Jr, “Temperature Dependence of the Energy Gap in GaAs and GaP”, J. Appl. Phys. 40, 163 (1969).
M. D. Sturge, “Optical Absorption of Gallium Arsenide between 0.6 and 2.75 eV”, Phys. Rev. 127, 768 (1962).
D. D. Sell, H. C. Casey Jr., and K. W. Wecht, “Concentration dependence of the refractive index for n- and p-type GaAs between 1.2 and 1.8 eV”, J. Appl. Phys. 45, 2650 (1974).
P. Lautenschlager, M. Garriga, S. Logothetidis, and M. Cardona, “Interband critical points of GaAs and their temperature dependence”, Phys. Rev. B 35, 9174 (1987).
M.-C. Wu and C.-C. Chen, “Photoluminescence of high-quality GaSb grown from Ga- and Sb rich solutions by liquid-phase epitaxy”, J. Appl. Phys. 72, 4275 (1992).
V. Bellani, S. Di Lemia, M. Geddo, G. Guizzetti, A. Bosacchi, S. Franchi and R. Magnanini, “Thermoreflectance Study of the direct energy gap of GaSb”, Solid State Comm. 104, 81 (1997).

C. Ghezzi, R. Magnanini, A. Parisini, B. Rotelli, L. Tarricone, A. Bosacchi, and S. Franchi, “Optical absorption near the fundamental absorption edge in Gasb”, Phys. Rev. B 52, 1463 (1995).
A. Joullié, A. Zein Eddin, and B. Girault, “Temperature dependence of the L_6\hat{ }c-G_6\hat{ }c energy gap in gallium antimonide”, Phys. Rev. B 23, 928 (1981).
E. Adachi, “Energy band parameters of InAs at various temperatures”, J. Phys. Soc. Jpn. 24, 1178 (1968).
J. R. Dixon and J. M. Ellis, “Optical properties of n-Type Indium Arsenide in the fundamental absorption edge region”, Phys. Rev. 123, 1560 (1961).
Z. M. Fang, K. Y. Ma, D. H. Jaw, R. M. Cohen, and G. B. Stringfellow, “Photoluminescence of InSb, InAs, and InAsSb grown by organometallic vapor phase epitaxy”, J. Appl. Phys. 67, 7034 (1990).
C. L. Littler and D. G. Seiler, “Temperature dependence of the energy gap of InSb using nonlinear optical techniques”, Appl. Phys. Lett. 46, 986 (1985).
D. Auvergne, J. Camassel, H. Mathieu, and M. Cardona, “Temperature dependence of the band structure of germanium and zinc-blende-type semiconductors”, Phys. Rev. B 9, 5168 (1974).
J. Camassel and D. Auvergne, “Temperature dependence of the fundamental edge of germanium and zinc-blende-type semiconductors”, Phys. Rev. B 12, 3258 (1975).
Y. P. Varshni, “Temperature dependence of the energy gap in semiconductors”, Physica 34, 149 (1967).
C. D. Thurmond, “The Standard Thermodynamic Functions for the Formation of Electrons and Holes in Ge, Si, GaAs, and GaP”, J. Electrochem. Soc. 122, 1133 (1975).
H. C. Casey, D. D. Sell, and K. W. Wecht, “Concentration dependence of the absorption coefficient for n- and p-type GaAs between 1.3 and 1.6 eV”, J. Appl. Phys. 46, 250 (1975).
G. M. Martin, “Optical assessment of the main electron trap in bulk semi-insulating GaAs”, Appl. Phys. Lett. 39, 747 (1981).

E. O. Kane, “Band Structure of Indium Antimonide”, J. Phys. Chem. Solids 1, 249 (1957).
M. Hass and B. W. Henvis, “Infrared lattice reflection spectra of III-V compound semiconductors”, J. Phys. Chem. Solids 23, 1099 (1962).
J. R. Dixon and J. K. Furdyna, “Measurement of the static dielectric constant of the InSb lattice via gyrotropic sphere resonances”, Solid State Communications 35, 195 (1980).
S. T. Schaefer, et al., “Absorption edge characteristics of GaAs, GaSb, InAs, and InSb”, J. Appl. Phys. 127, 165705 (2020).

What is claimed is:

1. A method for determining a characteristic of a direct-gap semiconductor, comprising:
measuring at least one optical constant of a first sample of a direct-gap semiconductor with an optical spectrometer;
calculating an estimated value of an optical parameter of the first sample of the direct-gap semiconductor based on fitting the model α_{g}(ln(1+e^{(hν-E}^{_{g}}^{)/pE}^{ᵤ}⁾/ln(2))^{p} to an optical absorption curve based on the at least one optical constant;
obtaining at least one second value of the optical parameter; and
calculating an estimated characteristic of the direct-gap semiconductor from the estimated value of the optical parameter and the obtained second value of the optical parameter.

2. The method of claim 1, further comprising:
obtaining at least one predetermined absorption characteristic of at least one known material as the second value of the optical parameter;
wherein the characteristic of the direct-gap semiconductor is a composition of the direct-gap semiconductor; and
wherein the optical parameter is an absorption characteristic.

3. The method of claim 2, wherein the model is fit using a least-squares fitting algorithm to measured optical absorption curves over a range spanning three times Eᵤ of the direct-gap semiconductor below the bandgap energy to 0.2 eV above the bandgap energy.

4. The method of claim 2, wherein the absorption characteristic is the bandgap energy.

5. The method of claim 1, further comprising the steps of:
measuring at least one optical constant of a second sample of a direct-gap semiconductor with the optical spectrometer; and
determining a second amplitude of an absorption knee of the second sample as the second value of the optical parameter, based on fitting the model α_{g}(ln(1+e^{(hν-E}^{_{g}}^{)/pE}^{ᵤ}⁾/ln(2))^{p} to an optical absorption curve based on the at least one optical constant of the second sample;
wherein the characteristic of the direct-gap semiconductor is an optical quality of the direct-gap semiconductor; and
wherein the optical parameter is a first amplitude of an absorption knee of the first sample.

6. The method of claim 5, wherein the model is fit using a least-squares fitting algorithm to measured optical absorption curves over a range spanning three times Eᵤ of the direct-gap semiconductor below the bandgap energy to 0.2 eV above the bandgap energy.

7. The method of claim 1, further comprising the steps of:
measuring at least one optical constant of a second sample of a direct-gap semiconductor with the optical spectrometer; and
determining a second Urbach energy parameter of the second sample as the second value of the optical parameter, based on fitting the model α_{g}(ln(1+e^{(hν-E}^{_{g}}^{)/pE}^{ᵤ}⁾/ln(2))^{p} to an optical absorption curve based on the at least one optical constant of the second sample;
wherein the characteristic of the direct-gap semiconductor is an optical quality of the direct-gap semiconductor; and
wherein the optical parameter is a first Urbach energy of the first sample.

8. The method of claim 7, wherein the model is fit using a least-squares fitting algorithm to measured optical absorption curves over a range spanning three times Eᵤ of the direct-gap semiconductor below the bandgap energy to 0.2 eV above the bandgap energy.

9. The method of claim 1, wherein the direct-gap semiconductor comprises a material selected from the group consisting of Ga, As, In, and Sb.

10. A method for determining a temperature of a direct-gap semiconductor comprising:
measuring at least one optical constant of a sample of a direct-gap semiconductor with an optical spectrometer;
determining a bandgap energy of the sample based on fitting the model α_{g}(ln(1+e^{(hν-E}^{_{g}}^{)/pE}^{ᵤ}⁾/ln(2))^{p} to an optical absorption curve based on the at least one optical constant;
comparing the bandgap energy of the sample to a known absorption characteristic of a reference material; and
calculating a temperature of the first sample based on a temperature dependence of the bandgap energy of the first sample and the bandgap energy of the reference material.

11. The method of claim 10, wherein the model is fit using a least-squares fitting algorithm to measured optical absorption curves over a range spanning three times Eᵤ of the direct-gap semiconductor below the bandgap energy to 0.2 eV above the bandgap energy.

12. The method of claim 10, wherein the absorption characteristic is the bandgap energy.

13. The method of claim 1, wherein the direct-gap semiconductor comprises a material selected from the group consisting of Ga, As, In, and Sb.

14. A system for determining a characteristic of a direct-gap semiconductor, comprising:
a spectroscopic device configured to measure at least one optical constant of a sample of a direct-gap semiconductor;
a computing device communicatively connected to the spectroscopic device, comprising a processor and a non-transitory computer-readable medium with instructions stored thereon, which when executed by a processor, perform steps comprising:
calculating an estimated value of an optical parameter of the first sample of the direct-gap semiconductor based on fitting the model α_{g}(ln(1+e^{(hν-E}^{_{g}}^{)/pE}^{ᵤ}⁾/ln(2))^{p} to an optical absorption curve based on the at least one optical constant;
obtaining at least one second value of the optical parameter; and
calculating an estimated characteristic of the direct-gap semiconductor from the estimated value of the optical parameter and the obtained second value of the optical parameter.

15. The system of claim 14, further comprising an optical coupling medium positioned between the spectroscopic device and the sample of the direct-gap semiconductor.

16. The system of claim 14, the steps further comprising:
obtaining at least one predetermined absorption characteristic of at least one known material as the second value of the optical parameter;
wherein the characteristic of the direct-gap semiconductor is a composition of the direct-gap semiconductor; and
wherein the optical parameter is an absorption characteristic.

17. The system of claim 16, wherein the model is fit using a least-squares fitting algorithm to measured optical absorption curves over a range spanning three times E, of the direct-gap semiconductor below the bandgap energy to 0.2 eV above the bandgap energy.

18. The system of claim 16, wherein the absorption characteristic is the bandgap energy.

19. The system of claim 14, the steps further comprising:
measuring at least one optical constant of a second sample of a direct-gap semiconductor with the optical spectrometer; and
determining a second amplitude of an absorption knee of the second sample as the second value of the optical parameter, based on fitting the model α_{g}(ln(1+e^{(hν-E}^{_{g}}^{)/pE}^{ᵤ}⁾/ln(2))^{p} to an optical absorption curve based on the at least one optical constant of the second sample;
wherein the characteristic of the direct-gap semiconductor is an optical quality of the direct-gap semiconductor; and
wherein the optical parameter is a first amplitude of an absorption knee of the first sample.

20. The system of claim 19, wherein the model is fit using a least-squares fitting algorithm to measured optical absorption curves over a range spanning three times Eᵤ of the direct-gap semiconductor below the bandgap energy to 0.2 eV above the bandgap energy.
